(19) United States
(12) Patent Application Publication
(10) Pub. No.: US 2010/0140641 A1
(43) Pub. Date: Jun. 10, 2010

(54) SEMICONDUCTOR LIGHT EMITTING APPARATUS INCLUDING SEMICONDUCTOR LIGHT EMITTING DEVICE, RED PHOSPHOR AND GREEN PHOSPHOR, AND IMAGE DISPLAY USING THE SEMICONDUCTOR LIGHT EMITTING APPARATUS

(76) Inventors: Junichi Kinomoto, Osaka (JP); Kenichi Yoshimura, Osaka (JP)

Correspondence Address: BIRCH STEWART KOLASCH & BIRCH, PO BOX 747, FALLS CHURCH, VA, 22040-0747, US

(21) Appl. No.: 12/613,640

(22) Filed: Nov. 6, 2009

(30) Foreign Application Priority Data
Dec. 10, 2008 (JP) 2008-314636(P)

(51) Int. Cl. H01L 33/00

(52) U.S. Cl. 257/98; 257/E33.061

(57) ABSTRACT

A semiconductor light emitting apparatus including a semiconductor light emitting device, a green phosphor emitting green light and a red phosphor emitting red light is provided. The green phosphor is a rare earth activated inorganic phosphor, and the red phosphor is a semiconductor particle phosphor. The minimum among respective differences between respective wavelengths at local minima of an absorption spectrum of the red phosphor and the peak wavelength of an emission spectrum of the green phosphor is not more than 25 nm. An image display including the semiconductor light emitting apparatus is also provided.

This nonprovisional application is based on Japanese Patent Application No. 2008-314636 filed on Dec. 10, 2008 with the Japan Patent Office, the entire contents of which are hereby incorporated by reference.

### BACKGROUND OF THE INVENTION

1. Field of the Invention

The present invention relates to a semiconductor light emitting apparatus including a semiconductor light emitting device, a red phosphor and a green phosphor, and to an image display using the semiconductor light emitting apparatus.

2. Description of the Background Art

Recently, competition in development of a backlight light source for a small-sized liquid crystal display (LCD) has been increasing. In the field of the liquid crystal display, various types of backlight light sources have been proposed. Currently, however, no light emission scheme for a backlight light source that achieves both of a high brightness and a high color reproducibility has been found. The color reproducibility of a backlight light source is commonly evaluated by means of an NTSC ratio. The NTSC ratio is calculated as a ratio of an area of a triangle formed by connecting respective chromaticity coordinates (u′, v′) positions of red, green and blue in the CIE 1976 chromaticity diagram to the area of the triangle formed by connecting respective chromaticity coordinates (u′, v′) positions of red, green and blue (red (0.498, 0.519), green (0.076, 0.576), blue (0.152, 0.196)) in the CIE 1976 chromaticity diagram specified by the NTSC (National Television System Committee).

Currently, as a backlight light source for an LCD, a semiconductor light emitting apparatus is used that generates white light by combining a semiconductor light emitting device emitting blue light with a peak wavelength of around 450 nm and excitation light, and a wavelength converter including a yellow phosphor excited by the excitation light emitted from the semiconductor light emitting device to emit yellow light. As the yellow phosphor, trivalent-cerium-activated (Y, Gd)₃(Al, Ga)₅O₁₂ phosphor or divalent-europium-activated (Sr, Ba, Ca)₂SiO₄ phosphor, for example, is used.

In the case where the semiconductor light emitting apparatus including the yellow phosphor is used as a backlight light source for an LCD, however, the NTSC ratio is a relatively low ratio of approximately 70%. Therefore, it is desired to further increase the NTSC ratio of a backlight light source for an LCD.

Japanese Patent Laying-Open No. 2004-287323 (Patent Document 1) proposes two types of backlight light sources each using a light emitting diode (LED). One of the backlight light sources of Patent Document 1 has a structure including a red LED, a green LED and a blue LED in one package. The backlight light source having this structure is superior in that the NTSC ratio can exceed 100%. A desired color, however, is difficult to generate, since respective drive characteristics of the red, green and blue LEDs are different from each other. Moreover, the structure of the backlight light source has respective drive circuits for the red, green and blue LEDs, and thus the structure is complicated and is difficult to be adapted to mobile applications where a small size is preferred.

Patent Document 1 discloses another backlight light source. This backlight light source uses an LED emitting ultraviolet light to excite a red phosphor emitting red light, a green phosphor emitting green light and a blue phosphor emitting blue light. The backlight light source is thus configured to emit red, green and blue light. A blue phosphor emitting blue light with a high brightness and a preferred wavelength range, however, has not been found.

Japanese Patent Laying-Open No. 2005-255895 (Patent Document 2) discloses a semiconductor light emitting apparatus including a semiconductor light emitting device emitting blue light, a green phosphor and a red phosphor. The semiconductor light emitting device generates excitation light to cause the green phosphor to emit green light and the red phosphor to emit red light. The red light, green light and blue light are mixed to generate white light. The semiconductor light emitting device emitting blue light can thus be used to generate red, green and blue light without requiring a blue phosphor suitable for a backlight light source. Even if the semiconductor light emitting apparatus of Patent Document 2 is used as a backlight light source, however, the color reproducibility is insufficient and further improvement of the color reproducibility is required.

Japanese Patent Laying-Open No. 2008-021988 (Patent Document 3) discloses a technique according to which a semiconductor particle phosphor is used as a red phosphor so that a narrower half width of the emission spectrum of the red phosphor can be obtained. The color reproducibility of a semiconductor light emitting apparatus including this red phosphor is thus improved.

### SUMMARY OF THE INVENTION

While the semiconductor light emitting apparatus including the red phosphor as disclosed in Patent Document 3 indeed tends to improve the color reproducibility of an image display using this semiconductor light emitting apparatus, a semiconductor light emitting apparatus achieving a still higher color reproducibility is desired. In addition, because the conventional semiconductor light emitting apparatuses are not always excellent in terms of luminous efficiency, there has been a demand for improvement of the luminous efficiency of the semiconductor light emitting apparatuses.

The present invention has been made in view of the current circumstances as described above, and an object of the invention is to provide a semiconductor light emitting apparatus achieving both of a high color reproducibility and a high luminous efficiency, and an image display using the semiconductor light emitting apparatus.

The inventors of the present invention have conducted thorough studies on a semiconductor light emitting apparatus including a red phosphor and a green phosphor in combination, in order to provide the semiconductor light emitting apparatus achieving both of a high color reproducibility and a high luminous efficiency. It has consequently been found that a semiconductor light emitting apparatus achieving both of a high color reproducibility and a high luminous efficiency can be provided by using a rare earth activated inorganic phosphor as a green phosphor and a semiconductor particle phosphor as a red phosphor in the semiconductor light emitting apparatus, and appropriately adjusting the wavelength at a local minimum of an absorption spectrum of the red phosphor and the peak wavelength of an emission spectrum of the green phosphor.

Specifically, a semiconductor light emitting apparatus of the present invention includes a semiconductor light emitting device, a green phosphor emitting green light and a red phosphor emitting red light. The green phosphor is a rare earth activated inorganic phosphor, the red phosphor is a semiconductor particle phosphor, and a minimum among respective differences between respective wavelengths at local minima of an absorption spectrum of the red phosphor and a peak wavelength of an emission spectrum of the green phosphor is not more than 25 nm.

Preferably, one of respective wavelengths at the local minima of the absorption spectrum of the red phosphor is identical to the peak wavelength of the emission spectrum of the green phosphor.

Preferably, the red phosphor selectively absorbs light in a wavelength region at an emission intensity of not more than 30% of a maximum emission intensity of the emission spectrum of the green phosphor.

Preferably, the absorption spectrum of the red phosphor has a local minimum in a range of 500 to 570 nm.

Preferably, in the absorption spectrum of the red phosphor, a local minimum of absorbance in a range of 500 to 570 nm is not more than 30% of a local maximum of absorbance in a range of 440 to 460 nm.

Preferably, an emission spectrum of the red phosphor has a half width of not more than 45 nm.

Preferably, an emission spectrum of the red phosphor has a peak wavelength in a range of 620 to 640 nm.

Preferably, a standard deviation of a particle size distribution of the red phosphor is within 20% of an average particle size of the red phosphor.

Preferably, the red phosphor has a core and shell structure.

Preferably, the red phosphor is a group II-VI semiconductor particle phosphor or group III-V semiconductor particle phosphor.

Preferably, the red phosphor is a semiconductor particle phosphor of a mixed crystal containing at least three elements.

Preferably, the red phosphor is a semiconductor particle phosphor of InGaP, InGaN or ZnCdSe.

Preferably, the emission spectrum of the green phosphor has a peak wavelength in a range of not less than 525 nm and not more than 545 nm, and the emission spectrum of the green phosphor has a half width of not more than 55 nm.

Preferably, the green phosphor is an oxynitride phosphor.

Preferably, the green phosphor is Eu activated β-SiAlON.

Preferably, the semiconductor light emitting device is a GaN semiconductor light emitting device.

Preferably, an emission spectrum of the semiconductor light emitting device has a peak wavelength in a range of 420 to 480 nm.

Preferably, an emission spectrum of the semiconductor light emitting device has a peak wavelength in a range of 440 to 460 nm.

Preferably, an emission spectrum of the semiconductor light emitting device has a peak wavelength in a range of 390 to 420 nm.

The prevent invention also provides an image display including the above-described semiconductor light emitting apparatus and a color filter.

The semiconductor light emitting apparatus and the image display of the present invention are configured in the above-described manner. Accordingly, the semiconductor light emitting apparatus achieving both of an improved color reproducibility and an improved luminous efficiency, as well as the image display using the semiconductor light emitting apparatus can be provided.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic perspective view showing an example of an image display of the present invention.

FIG. 2 is a schematic cross-sectional view showing an example of a semiconductor light emitting apparatus of the present invention.

FIG. 3 is a schematic exploded perspective view showing a structure of a liquid crystal display unit used for an image display of the present invention.

FIG. 4 is a graph showing respective transmission spectrums of a red color filter, a green color filter and a blue color filter used for a liquid crystal display unit of an image display of the present invention.

FIG. 5 is a graph showing respective emission spectrums of red phosphors each used for a semiconductor light emitting apparatus of the present invention.

FIG. 6 is a graph showing respective absorption spectrums of red phosphors each used for a semiconductor light emitting apparatus of the present invention.

FIG. 7 is a graph showing respective emission spectrums of red phosphors for comparative examples each used for a semiconductor light emitting apparatus.

FIG. 8 is a graph showing respective absorption spectrums of red phosphors for comparative examples each used for a semiconductor light emitting apparatus.

FIG. 9 is a graph showing respective emission spectrums of red phosphors for comparative examples each used for a semiconductor light emitting apparatus.

FIG. 10 is a graph showing respective absorption spectrums of red phosphors for comparative examples each used for a semiconductor light emitting apparatus.

FIG. 11 is a graph showing respective emission spectrums of red phosphors each used for a semiconductor light emitting apparatus of the present invention.

FIG. 12 is a graph showing respective absorption spectrums of red phosphors each used for a semiconductor light emitting apparatus of the present invention.

FIG. 13 is a graph showing respective emission spectrums of red phosphors for comparative examples each used for a semiconductor light emitting apparatus.

FIG. 14 is a graph showing respective absorption spectrums of red phosphors for comparative examples each used for a semiconductor light emitting apparatus.

FIG. 15 is a graph showing respective emission spectrums of red phosphors each used for a semiconductor light emitting apparatus of the present invention.

FIG. 16 is a graph showing respective absorption spectrums of red phosphors each used for a semiconductor light emitting apparatus of the present invention.

FIG. 17 is a graph showing respective emission spectrums of red phosphors for comparative examples each used for a semiconductor light emitting apparatus.

FIG. 18 is a graph showing respective absorption spectrums of red phosphors for comparative examples each used for a semiconductor light emitting apparatus.

FIG. 19 is a graph showing an emission spectrum of a red phosphor used for a semiconductor light emitting apparatus of the present invention.

FIG. 20 is a graph showing an absorption spectrum of a red phosphor used for a semiconductor light emitting apparatus of the present invention.

FIG. 21 is a graph showing an emission spectrum of a red phosphor used for a semiconductor light emitting apparatus of the present invention.

FIG. 22 is a graph showing an absorption spectrum of a red phosphor used for a semiconductor light emitting apparatus of the present invention.

FIG. 23 is a graph showing an emission spectrum of a red phosphor used for a semiconductor light emitting apparatus of the present invention.

FIG. 24 is a graph showing an absorption spectrum of a red phosphor used for a semiconductor light emitting apparatus of the present invention.

FIG. 25 is a graph showing an emission spectrum of a red phosphor used for a semiconductor light emitting apparatus of the present invention.

FIG. 26 is a graph showing an absorption spectrum of a red phosphor used for a semiconductor light emitting apparatus of the present invention.

FIG. 27 is a graph showing an emission spectrum of a red phosphor used for a semiconductor light emitting apparatus of the present invention.

FIG. 28 is a graph showing an absorption spectrum of a red phosphor used for a semiconductor light emitting apparatus of the present invention.

FIG. 29 is a graph showing an emission spectrum of a red phosphor used for a semiconductor light emitting apparatus of the present invention.

FIG. 30 is a graph showing an absorption spectrum of a red phosphor used for a semiconductor light emitting apparatus of the present invention.

FIG. 31 is a graph showing an emission spectrum of a red phosphor used for a semiconductor light emitting apparatus of the present invention.

FIG. 32 is a graph showing an absorption spectrum of a red phosphor used for a semiconductor light emitting apparatus of the present invention.

FIGS. 33 and 34 are each a graph showing an emission spectrum of a green phosphor used for a semiconductor light emitting apparatus of the present invention.

FIGS. 35 to 40 are each a graph showing an emission spectrum of an example of a semiconductor light emitting apparatus of the present invention.

FIG. 41 is a graph showing an example of the relation between an absorption spectrum of a red phosphor and an emission spectrum of a green phosphor used for a semiconductor light emitting apparatus of the present invention.

FIG. 42 is a graph showing an example of the relation between an absorption spectrum of a red phosphor and an emission spectrum of a green phosphor used for a semiconductor light emitting apparatus for a comparative example.

FIG. 43 is a graph showing a relation between an absorption spectrum of a red phosphor and a luminous efficiency of a semiconductor light emitting apparatus for which the red phosphor is used.

### DESCRIPTION OF THE PREFERRED EMBODIMENTS

Embodiments of the present invention will be hereinafter described. In the drawings of the present invention, like or corresponding components are denoted by like reference characters.

<Image Display>

FIG. 1 is a schematic exploded perspective view showing a preferred example of an image display according to the present invention. Image display 100 of the present invention includes a plurality of (six in FIG. 1) semiconductor light emitting apparatuses 10 arranged on a side of a transparent or translucent light guide plate 103. A liquid crystal display unit 105 is provided adjacently to an upper surface of light guide plate 103. Liquid crystal display unit 105 is constituted of a plurality of liquid crystal display devices 110. Emission light 102 from semiconductor light emitting apparatuses 10 is scattered within light guide plate 103 and resultant scattered light 104 illuminates the whole surface of liquid crystal display unit 105. As a backlight light source of image display 100, semiconductor light emitting apparatuses 10 emitting white light are used.

Image display 100 of the present invention includes semiconductor light emitting apparatus 10 having a semiconductor light emitting device, a green phosphor emitting green light and a red phosphor emitting red light, and includes a color filter. The green phosphor is a rare earth activated inorganic phosphor, and the red phosphor is a semiconductor particle phosphor. The minimum among respective differences between respective wavelengths at local minima of an absorption spectrum of the red phosphor and the peak wavelength of an emission spectrum of the green phosphor is not more than 25 nm. In terms of further enhancement of the color reproducibility and the luminous efficiency, it is more preferable that the minimum among respective differences between respective wavelengths at local minima of the absorption spectrum of the red phosphor and the peak wavelength of the emission spectrum of the green phosphor is not more than 15 nm, and it is still more preferable that one of respective wavelengths at the local minima of the absorption spectrum of the red phosphor is identical to the peak wavelength of the emission spectrum of the green phosphor.

<Semiconductor Light Emitting Apparatus>

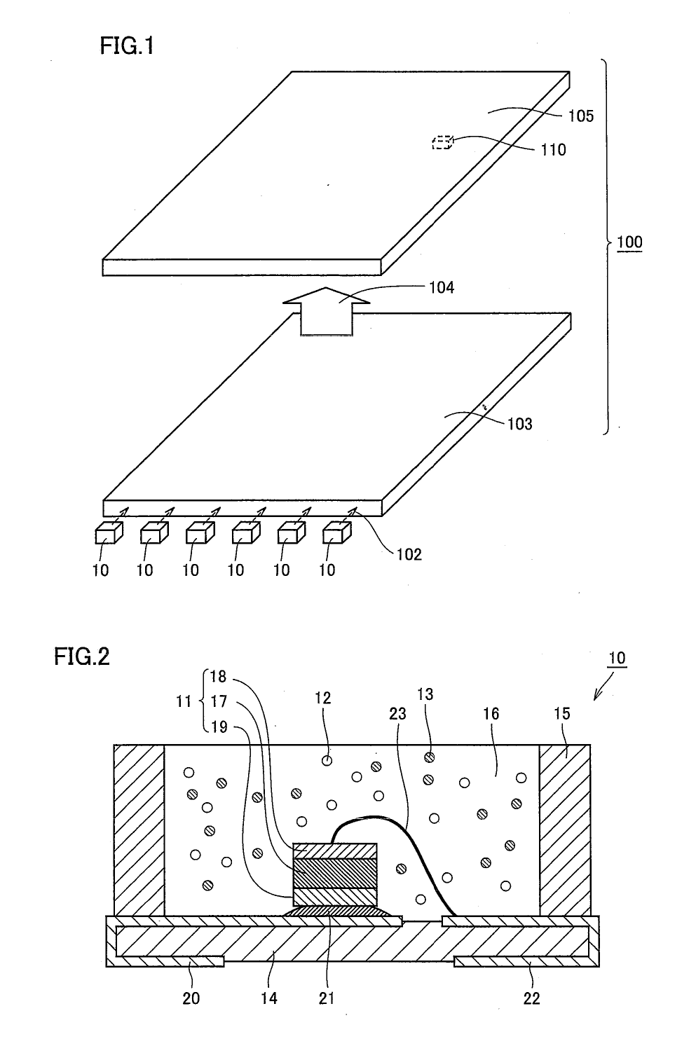

FIG. 2 is a schematic cross-sectional view showing an example of the semiconductor light emitting apparatus of the present invention. As shown in FIG. 2, semiconductor light emitting apparatus 10 of the present invention includes a printed circuit board 14 serving as a base, and a semiconductor light emitting device 11 and a resin frame 15 mounted on the printed circuit board. The inside of resin frame 15 is filled with a molded resin 16 formed of a translucent resin in which a green phosphor 12 and a red phosphor 13 are dispersed. This molded resin 16 seals semiconductor light emitting device 11.

As shown in FIG. 2, semiconductor light emitting apparatus 10 includes therein semiconductor light emitting device 11, green phosphor 12 and red phosphor 13, and semiconductor light emitting device 11 emits blue excitation light. Green phosphor 12 and red phosphor 13 are excited by the excitation light from semiconductor light emitting device 11 to emit green light and red light respectively. The blue excitation light, green light and red light are mixed and semiconductor light emitting apparatus 10 accordingly emits white light. Semiconductor light emitting apparatus 10 of the present invention is not limited to the structure shown in FIG. 2, and a conventionally known common structure may be used for the semiconductor light emitting apparatus.

Semiconductor light emitting apparatus 10 of the present invention includes semiconductor light emitting device 11, green phosphor 12 emitting green light and red phosphor 13 emitting red light, green phosphor 12 is a rare earth activated inorganic phosphor, red phosphor 13 is a semiconductor particle phosphor, and the minimum among respective differences between respective wavelengths at local minima of the absorption spectrum of red phosphor 13 and the peak wavelength of the emission spectrum of green phosphor 12 is not more than 25 nm. In terms of enhancement of the color reproducibility and the luminous efficiency, it is more preferable that the minimum among respective differences between respective wavelengths at local minima of the absorption spectrum of red phosphor 13 and the peak wavelength of the emission spectrum of green phosphor 12 is not more than 15 nm, and it is still more preferable that one of respective wavelengths at the local minima of the absorption spectrum of red phosphor 13 and the peak wavelength of the emission spectrum of green phosphor 12 are identical to each other.

<Semiconductor Light Emitting Device>

Semiconductor light emitting device 11 used for the semiconductor light emitting apparatus of the present invention may have a conventionally known common composition. Examples of the semiconductor light emitting device may include, for example, GaN semiconductor light emitting device, ZnSe semiconductor light emitting device, SiC semiconductor light emitting device, and the like. Among them, the GaN semiconductor light emitting device is particularly preferable for use, since the GaN semiconductor light emitting device can be used to provide a semiconductor light emitting apparatus having a high luminous efficiency and being highly suitable for practical use.

Regarding the structure of semiconductor light emitting device 11 used for semiconductor light emitting apparatus 10 of the present invention, a structure as shown in FIG. 2 for example may be used that includes an active layer 17, a p electrode 18 located on the top side of active layer 17 and an n electrode 19 located on the bottom side of active layer 17 that are provided to sandwich active layer 17 therebetween. N electrode 19 is electrically connected, via an electrically conductive adhesive 21, with an n electrode portion 20 provided along from the top surface to the bottom surface of printed circuit board 14. P electrode 18 is electrically connected via a metal wire 23 with a p electrode portion 22 provided separately from n electrode portion 20 along from the top surface to the bottom surface of printed circuit board 14.

The peak wavelength of an emission spectrum of semiconductor light emitting device 11 used for semiconductor light emitting apparatus 10 of the present invention is preferably 420 to 480 nm, in terms of the color reproducibility of a blue point on a chromaticity diagram of the image display. For semiconductor light emitting device 11 having a peak wavelength of the emission spectrum in a wavelength range of 420 to 480 nm, active layer 17 of InGaN for example may be used.

It is more preferable that the peak wavelength of the emission spectrum of semiconductor light emitting device 11 is 440 to 460 nm, in terms of improvement of wavelength matching with a transmission spectrum of a blue color filter that is generally used for the image display as described later. In terms of improvement of the luminous efficiency of semiconductor light emitting device 11, the peak wavelength of the emission spectrum of semiconductor light emitting device 11 may be 390 to 420 nm.

<Red Phosphor>

A semiconductor particle phosphor is used as red phosphor 13 dispersed in molded resin 16 of semiconductor light emitting apparatus 10 of the present invention. Red phosphor 13 may be any as long as satisfactory wavelength matching with the transmission spectrum of a red color filter that is commonly used for liquid crystal display device 110, as well as a high luminous efficiency for red of the image display in which the red phosphor is used are achieved. Red phosphor 13 that is preferably used for semiconductor light emitting apparatus 10 of the present invention will be described.

(1) Local Minimum of Absorption Spectrum

Red phosphor 13 used for semiconductor light emitting apparatus 10 of the present invention has a feature that the minimum among respective differences between respective wavelengths at local minima of the absorption spectrum of red phosphor 13 and the peak wavelength of the emission spectrum of green phosphor 12 is 25 nm or less.

In a conventional semiconductor light emitting apparatus, green light emitted from a green phosphor is absorbed by a red phosphor, resulting in a large loss of the green light. Accordingly, the luminous efficiency of the semiconductor light emitting apparatus is likely to deteriorate. In contrast, in the case where the minimum among respective differences between respective wavelengths at local minima of the absorption spectrum of red phosphor 13 (namely, the local minima correspond to valleys of the absorption spectrum of red phosphor 13, for example) and the peak wavelength of the emission spectrum of green phosphor 12 is equal to or less than a half of the half width of green phosphor 12 as specified by the present invention, absorption of the light emitted from green phosphor 12 by red phosphor 13 can be reduced. Further, the green light can be selectively transmitted and accordingly the luminous efficiency of semiconductor light emitting apparatus 10 can be improved.

Thus, it is preferable that the minimum among respective differences between respective wavelengths at local minima of the absorption spectrum of red phosphor 13 and the peak wavelength of the emission spectrum of green phosphor 12 is not more than a half of the half width of green phosphor 12. Specifically, the half width of green phosphor 12 is preferably not more than 55 nm as described later. Therefore, it is more preferable that the minimum among respective differences between respective wavelengths at local minima of the absorption spectrum of red phosphor 13 and the peak wavelength of the emission spectrum of green phosphor 12 is not more than 25 nm. It is most preferable that one of respective wavelengths at the local minima of the absorption spectrum of red phosphor 13 is identical to the peak wavelength of the emission spectrum of green phosphor 12.

For the purpose of satisfying the condition that a wavelength at a local minimum of the absorption spectrum of red phosphor 13 is closer to the peak wavelength of the emission spectrum of green phosphor 12, it is preferable that a wavelength at a local minimum of the absorption spectrum of red phosphor 13 is not less than 500 nm and not more than 570 nm. Further, for the purpose of satisfying the condition that one of respective wavelengths at the local minima of the absorption spectrum of red phosphor 13 is identical to the peak wavelength of the emission spectrum of green phosphor 12, it is more preferable that the peak wavelength of the emission spectrum of green phosphor 12 is not less than 525 nm and not more than 545 nm.

(2) Local Maximum of Absorption Spectrum

It is preferable that red phosphor 13 selectively absorbs light in a wavelength region corresponding to an emission intensity of not more than 30% of the maximum emission intensity of the emission spectrum of green phosphor 12 (namely absorbs light corresponding to a bottom region of the emission spectrum of green phosphor 12).

Regarding red phosphor 13 used for a conventional semiconductor light emitting apparatus, the light in a wavelength region corresponding to an emission intensity of not more than 30% of the maximum emission intensity of the emission spectrum of green phosphor 12 is absorbed by a color filter, and thus is not effectively used.

In contrast, in the case where red phosphor 13 selectively absorbs the light in a wavelength region corresponding to an emission intensity of not more than 30% of the maximum emission intensity of the emission spectrum of green phosphor 12, the light in the wavelength region, which is absorbed by the color filter and thus wasted in the conventional semiconductor light emitting apparatus, is wavelength-converted into red light. Thus, the light in this wavelength region can be effectively used as the red light and the luminous efficiency of semiconductor light emitting apparatus 10 can be improved.

Further, in the case where red phosphor 13 selectively absorbs the light in a wavelength region corresponding to an emission intensity of not more than 30% of the maximum emission intensity of the emission spectrum of green phosphor 12, the half width of the emission spectrum of green phosphor 12 can be made narrower. With the narrower half width of the emission spectrum of green phosphor 12, the color reproducibility of green can be improved.

(3) Characteristics of Absorption Spectrum

Regarding the absorption spectrum of red phosphor 13 used for semiconductor light emitting apparatus 10 of the present invention, it is preferable that the absorbance of red phosphor 13 is low near the peak wavelength of the emission spectrum of green phosphor 12. Further, it is preferable that the absorbance of red phosphor 13 is high in a wavelength region of blue light. Specifically, regarding the absorption spectrum of red phosphor 13, it is preferable that a local minimum of absorbance in a wavelength region of 500 to 570 nm is not more than 30% of a local maximum of absorbance in a wavelength region of 440 to 460 nm.

Red phosphor 13 having an absorption spectrum as specified above can be used to reduce a light conversion loss resulting from absorption of light near the peak wavelength of the emission spectrum of green phosphor 12 by red phosphor 13, as generated for example in a conventional semiconductor light emitting apparatus. Further, the excitation light emitted from semiconductor light emitting device 11 can excite red phosphor 13. Thus, the resultant synergetic effect can further improve the luminous efficiency of semiconductor light emitting apparatus 10. Here, the absorbance of red phosphor 13 can be measured by means of a spectrophotometer.

(4) Half Width

The half width of the emission spectrum of red phosphor 13 used for the present invention is preferably not more than 45 nm. With red phosphor 13 having an emission spectrum with a half width of not more than 45 nm, semiconductor light emitting apparatus 10 having a high color reproducibility of red can be realized. Further, in the case where the half width of the emission spectrum of red phosphor 13 is not more than 45 nm, the absorption spectrum of red phosphor 13 has a plurality of local maxima and a plurality of local minima. Accordingly, when red phosphor 13 and green phosphor 12 are used in combination, the absorbance of red phosphor 13 at wavelengths near the peak wavelength of the emission spectrum of green phosphor 12 can be made lower. Further, in the case where the half width of the emission spectrum of red phosphor 13 is not more than 45 nm, red phosphor 13 can have an absorption spectrum to selectively absorb light in a wavelength region corresponding to an emission intensity of not more than 30% of the maximum emission intensity of the emission spectrum of green phosphor 12. The resultant synergetic effect can improve the color reproducibility and the luminous efficiency of the semiconductor light emitting apparatus.

(5) Peak Wavelength

The peak wavelength of the emission spectrum of red phosphor 13 used for semiconductor light emitting apparatus 10 of the present invention is preferably not less than 620 nm and not more than 640 nm. If the peak wavelength of the emission spectrum of red phosphor 13 is less than 620 nm, the color reproducibility of red could be lower. On the contrary, if the peak wavelength of the emission spectrum of red phosphor 13 is larger than 640 nm, the emission is out of the luminosity curve of human eyes and red phosphor 13 excessively absorbs the light emitted from green phosphor 12. Consequently, the luminous efficiency of semiconductor light emitting apparatus 10 could be deteriorated.

(6) Material

Red phosphor 13 used for the present invention may be any as long as the red phosphor is a conventionally known semiconductor particle phosphor. In terms of the material for the red phosphor, examples of the material may include group IV-IV semiconductor material, group III-V compound semiconductor material, group II-VI compound semiconductor material, group I-VIII compound semiconductor material, group IV-VI compound semiconductor material, and the like. In terms of the number of elements contained in a mixed crystal, any of a binary compound semiconductor containing two different elements, and a mixed crystal semiconductor containing three or more different elements may be used. For the purpose of improving the luminous efficiency of semiconductor light emitting apparatus 10, it is preferable to use a semiconductor particle phosphor of a direct transition semiconductor material. For the purpose of efficiently emitting light in the visible wavelength region, it is more preferable to use a group II-VI semiconductor particle phosphor or group III-V semiconductor particle phosphor. For the purpose of improving flexibility in design of the emission spectrum and the absorption spectrum, it is still more preferable to use a semiconductor particle phosphor of a mixed crystal containing three or more different elements. In terms of easiness of manufacture, it is preferable to use a semiconductor particle phosphor of a mixed crystal containing four or less different elements. In the case where a semiconductor particle phosphor of a mixed crystal containing three or more different elements is used, the particle size of the semiconductor particle phosphor and the relative proportions of the elements in the ternary mixed crystal of the semiconductor particle phosphor can be changed to independently design the energy level of the semiconductor particle phosphor. Accordingly, the emission spectrum and the absorption spectrum of the red phosphor can be changed independently of each other. Thus, the image display using a mixed crystal of the semiconductor particle phosphor can achieve both of a high luminous efficiency and a high color reproducibility. This is for the reason that the absorption spectrum of the red phosphor appropriate for the emission spectrum of the green phosphor is designed and then the emission spectrum of the red phosphor can be independently varied.

Examples of the semiconductor particle phosphor of a binary compound that is to be used as a red phosphor as described above may include, for example, InP, InN, InAs, GaAs, CdSe, CdTe, PbS, PbSe, and PbTe. In terms of toxicity to human body and environmental load, it is more preferable to use InP or InN.

Examples of the semiconductor particle phosphor of a ternary mixed crystal may include, for example, InGaP, AlInP, InGaN, AlInN, ZnCdSe, ZnCdTe, PbSSe, PbSTe, and PbSeTe. It is preferable to use a group III-V mixed crystal semiconductor particle phosphor of InGaP or InGaN, since these materials are harmonious with the environment and the semiconductor particle phosphors less susceptible to the outside can be produced by using these materials. It is also preferable to use a group II-VI mixed crystal semiconductor particle phosphor of ZnCdSe, for the purpose of easily producing a semiconductor particle phosphor with a narrow particle size distribution.

(7) Structure

Regarding the structure of the red phosphor used for the present invention, the semiconductor particle phosphor with a common particle structure may be used.

The shape of a particle of the red phosphor may be irregular shape that is partially protruded for example, sphere, regular tetrahedron, or cube, for example. Since the semiconductor particle phosphor has a high ratio of the surface area to the volume of the particle, the shape of the particle can be changed to increase or decrease the surface area of the particle and accordingly change optical characteristics to a large extent.

In terms of the structure of the particle of the red phosphor, it is preferable to use a particle with a single core structure, a particle with a core/shell structure or a particle with a shell/core/shell structure, for example. For the purpose of alleviating any adverse influences of the outside and accordingly improving the durability of the red phosphor, it is preferable to use a particle with the core/shell structure or a particle with the shell/core/shell structure. For the purpose of easily producing the red phosphor, it is preferable to use a particle with the single core structure or a particle with the core/shell structure.

Here, the core refers to an emission part where electrons and holes are recombined to emit light. The shell refers to a protection part made from a material different from the core material and protects the core from adverse influences of the outside. The single core structure refers to a structure formed of the core only without shell, and the core/shell structure refers to a structure where at least a part of the surface of the core serving as a light emission region of the red phosphor is covered with the shell. A particle with the core/shell structure in which the band gap of the shell material is larger than the band gap of the core material can be used to achieve the electron confinement effect in the red phosphor and accordingly improve the luminous efficiency.

The shell/core/shell structure refers to a structure in which a core is formed to cover the surface of a particle-like shell located at the center and another shell is further formed thereafter. The shell/core/shell structure can achieve a greater electron confinement effect than the core/shell structure and accordingly further improve the luminous efficiency.

(8) Method for Synthesis

A particle with the core/shell structure to be used for the red phosphor of the present invention may be synthesized by any of conventionally known methods, including, for example, vapor phase synthesis, liquid phase synthesis, solid phase synthesis, and vacuums synthesis. In terms of adaptability to mass production, the liquid phase synthesis is preferred. In particular, hot-soap synthesis and reverse micelle synthesis, for example, are more preferred, since these synthesis methods can be used to synthesize a red phosphor with a high luminous efficiency of red light.

(9) Average Particle Size and Particle Size Distribution

It is preferable that the average particle size of red phosphor 13 used for the present invention is not less than 0.5 nm, and not more than twice as large as the Bohr radius of the material for the red phosphor, and satisfies the conditions that the average particle size is in the above-specified range and a required emission wavelength is achieved. If the average particle size of red phosphor 13 is less than 0.5 nm, there is a problem that the particle is too small and thus the particle does not stably exist and could be altered. If the average particle size of red phosphor 13 is more than twice as large as the Bohr radius of the material, there is a problem that the quantum confinement effect is insufficient and the emission wavelength cannot be controlled in the particle. Here, respective Bohr radii of InP, InN and CdSe are 8.3 nm, 7.0 nm and 4.9 nm.

Here, the particle size of the red phosphor refers to the numerical value representing the diameter of a particle of the red phosphor. In the case where a particle with the core/shell structure is used for the red phosphor, the particle size refers to the diameter of the core only, namely the dimension of the shell is not included in the particle size.

The standard deviation of the particle size distribution of red phosphor 13 is preferably within 20% of the average particle size of red phosphor 13. Under the condition that the standard deviation of the particle size distribution of red phosphor 13 is within 20% of the average particle size of red phosphor 13, the peak half width of the emission spectrum of red phosphor 13 is 45 nm or less. Accordingly, the color reproducibility of red of the semiconductor light emitting apparatus can be enhanced.

The standard deviation of the particle size distribution of red phosphor 13 is determined in the following way. Respective particle sizes of 20 red phosphor particles are measured through direct observation by a TEM (transmission electron microscope), the average of the particle sizes is calculated, and the square root of the sum of respective variances of the particle sizes of the red phosphor relative to the average particle size is divided by the average particle size. The standard deviation refers to the resultant value determined in the above-described manner and expressed in percentage.

Red phosphor 13 with particles satisfying the condition that the standard deviation of the particle size distribution of red phosphor 13 is within 20% of the average particle size of red phosphor 13 can be used to reduce variation of energy levels of individual semiconductor particles of the phosphor. Accordingly, the red phosphor that selectively absorbs light of only a specific wavelength can be produced. The absorption spectrum of such red phosphor 13 has one or more local maxima and one or more local minima.

As a method for collecting particles of similar sizes of red phosphor 13, any of conventionally known classification methods may be used. The classification methods may include, for example, electrophoresis, size selective precipitation, and photo-assist etching.

The size selective precipitation refers to a classification method according to which a classification process, including a precipitation operation for precipitating particles of a specific size by means of a poor solvent and a dispersion operation for dispersing the precipitated specific particles by means of a good solvent, is repeated multiple times, so that a solution is obtained in which particles with respective sizes in a specific particle size range are dispersed.

The size selective precipitation is more specifically described using an example of a solution in which red phosphor particles with different sizes are dispersed. A small amount of a poor solvent with a solubility different from the solution containing dispersed red phosphor is added to change the solubility of the solution and precipitate red phosphor particles with a relatively large size. The precipitated red phosphor particles are collected to which a good solvent is added to change the solubility of the solution and disperse the phosphor again in the solvent. The precipitation and re-dispersion are repeated so that a solution can be obtained where red phosphor particles of respective sizes in a specific range are dispersed.

<Green Phosphor>

A rare earth activated inorganic phosphor is used as green phosphor 12 dispersed in molded resin 16 of semiconductor light emitting apparatus 10 of the present invention. Among rare earth activated inorganic phosphors, an oxynitride phosphor is preferably used since the oxynitride phosphor has an excellent durability. For the purpose of improving the color reproducibility of green, it is preferable to use a green phosphor with a smaller half width of the emission spectrum. It is particularly preferable to use Eu activated β-SiAlON phosphor as a rare earth activated inorganic phosphor satisfying the above-described conditions.

The half width of the emission spectrum of green phosphor 12 is preferably not more than 55 nm, in terms of the wavelength matching with a transmission spectrum of a green color filter commonly used for image display 100 for which semiconductor light emitting apparatus 10 with green phosphor 12 is used. For the purpose of improving the color reproducibility of green of the image display, it is more preferable that the half width of the emission spectrum of green phosphor 12 is not more than 50 nm.

The peak wavelength of the emission spectrum of green phosphor 12 when green phosphor 12 is illuminated with the excitation light emitted from semiconductor light emitting device 11 is preferably in a wavelength region of not less than 525 nm and not more than 545 nm. Under the condition that the peak wavelength of the emission spectrum of green phosphor 12 is not less than 525 nm and not more than 545 nm, satisfactory wavelength matching with a commonly used green color filter is achieved. Thus, the emission of green phosphor 12 when used for the image display can be efficiently used.

The wavelength matching with the transmission spectrum of the green color filter is deteriorated when the peak wavelength of green phosphor 12 is less than 525 nm or larger than 545 nm. Accordingly, not only the brightness of the image display but also the color reproducibility of the image display could be deteriorated. Specifically, if the peak wavelength of green phosphor 12 is less than 525 nm, the emission spectrum of green phosphor 12 overlaps the transmission spectrum of a blue color filter, and thus the color reproducibility of blue could be deteriorated. On the contrary, if the peak wavelength of green phosphor 12 exceeds 540 nm, the emission spectrum of green phosphor 12 overlaps the transmission spectrum of a red color filter, and thus the color reproducibility of red could be deteriorated.

<Molded Resin>

In semiconductor light emitting apparatus 10 of the present invention, molded resin 16 used for sealing semiconductor light emitting device 11 may be any conventionally known molded resin 16 as long as the molded resin is a translucent resin used for this kind of application. Examples of such molded resin 16 may include, for example, translucent resin such as silicone resin, epoxy resin, acrylic resin, fluorine resin, polycarbonate resin, polyimide resin, and urea resin, and translucent inorganic material such as aluminum oxide, silicon oxide, and yttria. In semiconductor light emitting apparatus 10 of the present invention, green phosphor 12 and red phosphor 13 are dispersed in molded resin 16. Further, a blue phosphor (not shown) may be appropriately dispersed in the molded resin for obtaining desired white light.

The blend ratio between red phosphor 13, green phosphor 12 and the blue phosphor dispersed in molded resin 16 is not limited to a particular one and may be any as long as an emission spectrum representing desired white light is obtained on the screen of image display 100 when semiconductor light emitting device 10 is used for image display 100 and all color filters are fully opened.

<Liquid Crystal Display Device>

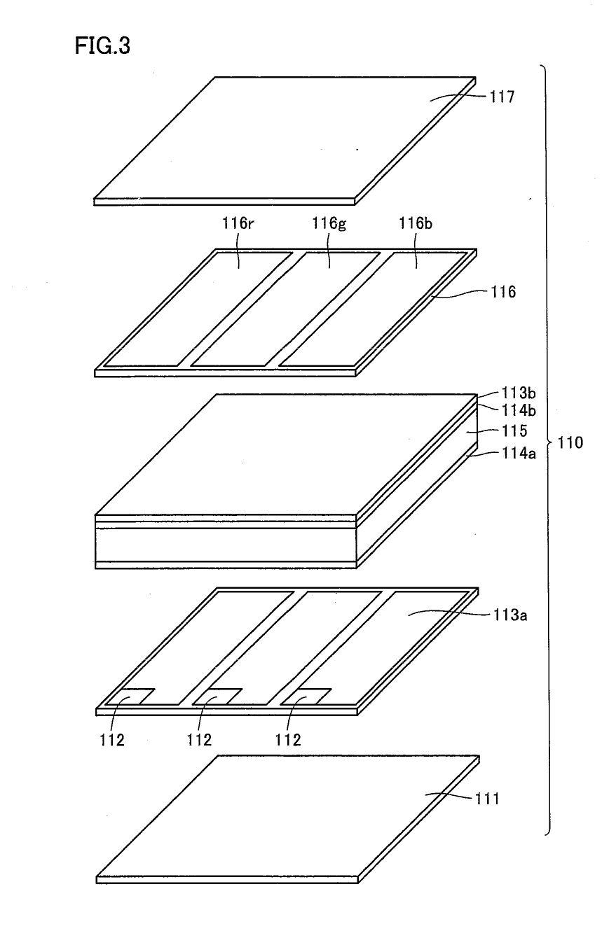

FIG. 3 is an enlarged exploded perspective view of liquid crystal display device 110 in liquid crystal display unit 105 shown in FIG. 1. As shown in FIG. 3, liquid crystal display device 110 constituting a part of liquid crystal display unit 105 of image display 100 of the present invention includes a polarizing plate 111, a transparent conductive film 113a (having a thin film transistor 112), an orientation film 114a, a liquid crystal layer 115, an orientation film 114b, an upper thin film electrode 113b, a color filter 116 for colors for displaying color pixels, and an upper polarizing plate 117 that are laid on each other in this order. The liquid crystal display device of the present invention is not limited to the structure shown in FIG. 3, and any conventionally known common structure may be used.

<Color Filter>

Color filer 116 used for liquid crystal display device 110 is divided into sections with respective sizes according to pixels of transparent conductive film 113a, and is specifically constituted of a red color filter 116r transmitting red light, a green color filter 116g transmitting green light and a blue color filter 116b transmitting blue light.

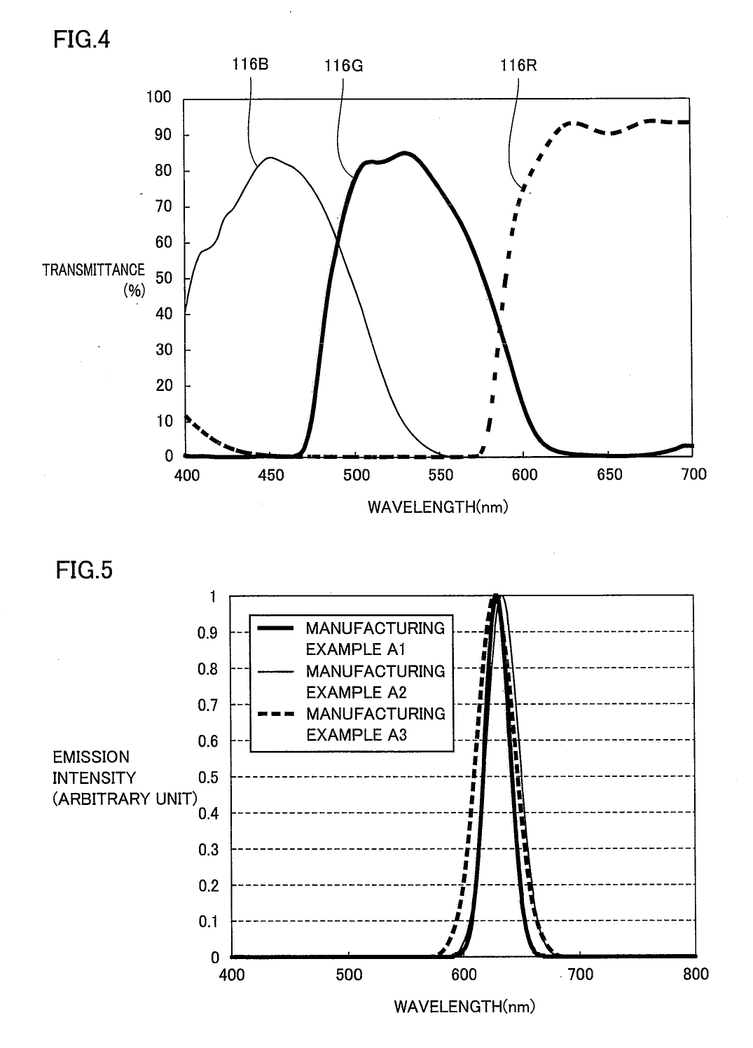

FIG. 4 is a graph showing respective transmission spectrums of the red, green and blue color filters used for the image display of the present invention, and the vertical axis represents transmission (%) and the horizontal axis represents wavelength (nm). Respective transmission spectrums for the colors of the color filters used for the image display of the present invention are not limited to only those illustrated using the graph of FIG. 4, and any conventionally known common color filter may be used.

It is preferable to use, for liquid crystal display unit 105 of image display 100 of the present invention, color filter 116 (namely red color filter 116r, green color filter 116g and blue color filter 116b) having the transmission spectrums as shown in FIG. 4. Such a color filter can be used to improve the wavelength matching with light emitted from the semiconductor light emitting apparatus, improve the color reproducibility of each color and improve the brightness of the screen of image display 100.

### EXAMPLES

In the following, the present invention will be described in more detail with reference to examples and comparative examples. The present invention, however, is not limited to them.

<Preparation of Red Phosphor>

Red phosphors for Manufacturing Examples A1 to A15 and Comparative Examples A1 to A9 were prepared through the procedures as described below.

### Manufacturing Examples A1-A3/Comparative Examples A1-A4

### Manufacturing Example A1

### Preparation of InP/ZnS Semiconductor Particle Phosphor

As a red phosphor for Manufacturing Example A1, a semiconductor particle phosphor with the core/shell structure in which a core of an InP fine crystal is covered with a shell of ZnS was prepared.

First of all, in a glove box with a dry nitrogen atmosphere, 200 mL of trioctylphosphine and 17.3 g of trioctylphosphine oxide were weighed out. Then, these were mixed and agitated for ten minutes to obtain a solvent mixture A.

Thereafter, to solvent mixture A in the glove box, 2.2 g (10.0 mmol) of indium trichloride as a group III metal element material and 2.5 g (10.0 mmol) of tris(trimethylsilyl)phosphine as a group V element material for semiconductor particles were added and mixed together. After mixed, they were agitated at 20° C. for ten minutes to obtain a raw material solution B.

Next, raw material solution B was heated at 350° C. for 72 hours while being agitated in a pressure vessel with a nitrogen atmosphere to synthesize the materials contained in raw material solution B and obtain a synthesis solution C. Then, synthesis solution C after the synthetic process was cooled by natural heat dissipation to room temperature, and then resultant synthesis solution C was retrieved in a dry nitrogen atmosphere.

This synthesis solution C underwent a classification process including an operation of adding 200 mL of dehydrated methanol as a poor solvent to precipitate a semiconductor particle phosphor and centrifuging the solution at 4000 rpm for ten minutes to settle the semiconductor particle phosphor, and an operation of adding dehydrated toluene to re-dissolve the semiconductor particle phosphor. The classification process was repeated ten times so as to obtain a dehydrated toluene solution D containing the semiconductor particle phosphor having a specific particle size. Then, from dehydrated toluene solution D, the dehydrated toluene solvent was evaporated so that a solid powder E was retrieved.

The diffraction peak of solid powder E was observed by a powder X-ray diffraction (XRD) apparatus (product name: Ultima IV (manufactured by Rigaku Corporation)), and the diffraction peak was found at the position of InP. It was thus found that solid powder E was an InP crystal. Further, solid powder E was directly observed by a transmission electron microscope (TEM) (product name: JEM-2100 (manufactured by JEOL Ltd.)) to measure respective particle sizes of 20 particles. The average particle size was determined by calculating the average of respective particle sizes. The average particle size of the InP crystal was 4.1 nm. Then, the square root of the sum of respective variances of the particle sizes of the red phosphor relative to the average particle size thereof was divided by the average particle size. The resultant quotient expressed in percentage was used to determine the standard deviation of the particle size distribution. The standard deviation of the particle size distribution was 8% of the average particle size.

Next, in a glove box with a dry nitrogen atmosphere, solid powder E and 17.3 g of trioctylphosphine oxide were added to 150 mL of trioctylphosphine, and they were mixed to obtain a raw material solution F. Further, to 50 mL, of trioctylphosphine, 1.6 g (13.0 mmol) of diethylzinc and 5.2 g (13.0 mmol) of trioctylphosphine sulfide were added, and these were mixed to obtain a raw material solvent G.

Raw material solution F obtained in the above-described manner was put in a three-neck flask and raw material solvent G was put in the drip inlets of the three-neck flask. Raw material solution F was heated to 180° C. and raw material solvent G was slowly dripped to obtain a synthesis solution H in which a semiconductor particle phosphor including a core of InP and a shell of ZnS surrounding the core was dispersed. Dehydrated methanol was dripped in synthesis solution H to precipitate the semiconductor particle phosphor, and the solution was centrifuged to retrieve the settled matter of synthesis solution H and obtain the red phosphor for Manufacturing Example A1.

A lattice image of the obtained red phosphor for Manufacturing Example A1 was observed through electron beam diffraction by a TEM. It was found that the semiconductor particle phosphor had the core/shell structure in which the core of InP was surrounded by the shell of ZnS. The semiconductor particle phosphor was illuminated by a lamp emitting light with a wavelength of 365 nm. Then, the phosphor emitted red light.

### Manufacturing Example A2

### Preparation of InP/ZnS Semiconductor Particle Phosphor

A semiconductor particle phosphor having the core/shell structure of InP/ZnS for Manufacturing Example A2 was prepared by a similar manufacturing method to Manufacturing Example A1 except for the number of times the classification process was repeated for obtaining the core of the semiconductor particles for Manufacturing Example A1.

Specifically, for Manufacturing Example A1, the classification process for the core including the precipitation and settling with the poor solvent (dehydrated methanol) and the re-dispersion with the good solvent (dehydrated toluene) was repeated ten times. For Manufacturing Example A2, the classification process including the precipitation and settling with a poor solvent and the re-dispersion with a good solvent was repeated seven times to prepare a red phosphor powder for Manufacturing Example A2. The obtained red phosphor powder for Manufacturing Example A2 had an average particle size of 4.1 nm and a standard deviation of 11% of the particle size of the InP core.

### Manufacturing Example A3

### Preparation of InP/ZnS Semiconductor Particle Phosphor

A semiconductor particle phosphor having the core/shell structure of InP/ZnS for Manufacturing Example A3 was prepared by a similar manufacturing method to Manufacturing Example A1 except for the number of times the classification process was repeated for obtaining the core of the semiconductor particles for Manufacturing Example A1.

Specifically, for Manufacturing Example A1, the classification process for the core including the precipitation and settling with the poor solvent and the re-dispersion with the good solvent was repeated ten times. For Manufacturing Example A3, the classification process including the precipitation and settling with a poor solvent and the re-dispersion with a good solvent was repeated five times to prepare a red phosphor powder for Manufacturing Example A3. The obtained red phosphor powder for Manufacturing Example A3 had an average particle size of 4.1 nm and a standard deviation of 15% of the particle size of the InP core.

FIG. 5 is a graph of respective emission spectrums of the red phosphors prepared for Manufacturing Examples A1 to A3, obtained by exciting the phosphors with light having a wavelength of 450 nm applied to the phosphors and observing respective emissions by means of a fluorescence spectrophotometer (product name: F-4500 (manufactured by Hitachi High-Technologies Corporation)). The vertical axis represents emission intensity (in an arbitrary unit) and the horizontal axis represents wavelength (nm). Table 1 shows the chromaticity coordinates of red light, the peak wavelength and the half width of the emission spectrum, respective compositions of the core and shell, the average particle size, and the standard deviation of each of the red phosphors obtained for Manufacturing Examples A1 to A3.

TABLE 1

| | | | red phosphor | | | | | | | | | |
|---|---|---|---|---|---|---|---|---|---|---|---|---|
| | | | core | | | | | | emission | | | |
| | | | average | | | | | | spectrum | | absorption spectrum | |
| | chromaticity | | particle | standard | | | shell | | peak | half | wavelength at local | |
| | coordinates | | size | deviation | | BG | compo- | BG | wavelength | width | minimum of absorbance | 500-570 nm/ |
| | u′ | v′ | [nm] | [%] | composition | [eV] | sition | [eV] | [nm] | [nm] | in 500-570 nm [nm] | 440-460 nm |
| *M.E. A1 | 0.537 | 0.519 | 4.1 | 8 | InP | 2.14 | ZnS | 3.56 | 629.6 | 25 | 526 | 28.6% |
| M.E. A2 | 0.541 | 0.519 | 4.1 | 11 | InP | 2.12 | ZnS | 3.56 | 633.9 | 32 | 526 | 32.4% |
| M.E. A3 | 0.508 | 0.524 | 4.1 | 15 | InP | 2.15 | ZnS | 3.56 | 628.0 | 38 | 527 | 35.4% |
| M.E. A4 | 0.538 | 0.519 | 4.1 | 9 | InN | 2.13 | ZnS | 3.56 | 630.9 | 27 | 534 | 40.3% |
| M.E. A5 | 0.508 | 0.524 | 4.1 | 13 | InN | 2.15 | ZnS | 3.56 | 627.0 | 35 | 522 | 58.9% |
| M.E. A6 | 0.525 | 0.521 | 4.1 | 15 | InN | 2.12 | ZnS | 3.56 | 634.4 | 39 | 523 | 61.0% |
| M.E. A7 | 0.523 | 0.522 | 5.3 | 6 | CdSe | 2.15 | ZnS | 3.56 | 626.4 | 21 | 542 | 19.6% |
| M.E. A8 | 0.525 | 0.521 | 5.3 | 12 | CdSe | 2.14 | ZnS | 3.56 | 630.7 | 34 | 544 | 26.3% |
| M.E. A9 | 0.498 | 0.525 | 5.3 | 15 | CdSe | 2.15 | ZnS | 3.56 | 625.6 | 38 | 547 | 28.7% |
| M.E. A10 | 0.540 | 0.519 | 4.1 | 4.5 | In_{0.6}Ga_{0.4}P | 2.14 | ZnS | 3.56 | 630.5 | 25.5 | 543 | 14.9% |
| M.E. A11 | 0.534 | 0.520 | 2.9 | 4.4 | In_{0.65}Ga_{0.35}N | 2.14 | ZnS | 3.56 | 628.5 | 25.3 | 518 | 22.3% |
| M.E. A12 | 0.534 | 0.520 | 2.9 | 4.4 | In_{0.6}Ga_{0.4}N | 2.14 | ZnS | 3.56 | 628.5 | 25.1 | 533 | 24.1% |
| M.E. A13 | 0.556 | 0.517 | 2.1 | 4.5 | In_{0.9}Ga_{0.1}N | 2.11 | ZnS | 3.56 | 636.4 | 25.4 | 545 | 23.4% |
| M.E. A14 | 0.536 | 0.520 | 4.1 | 5.4 | Zn_{0.1}Cd_{0.9}Se | 2.14 | ZnS | 3.56 | 629.2 | 24.3 | 536 | 18.8% |
| M.E. A15 | 0.514 | 0.521 | 4.1 | 11 | InP | 2.15 | — | — | 626.8 | 37 | 522 | 30.8% |
| **C.E. A1 | 0.468 | 0.530 | 4.1 | 27 | InP | 2.14 | ZnS | 3.56 | 628.5 | 55 | — | 38.6% |
| C.E. A2 | 0.427 | 0.536 | 4.1 | 39 | InP | 2.14 | ZnS | 3.56 | 629.4 | 72 | — | 35.3% |
| C.E. A3 | 0.576 | 0.514 | 4.2 | 11 | InP | 2.08 | ZnS | 3.56 | 647.4 | 35 | — | 35.2% |
| C.E. A4 | 0.479 | 0.528 | 4.0 | 11 | InP | 2.18 | ZnS | 3.56 | 618.3 | 33 | 510 | 40.3% |
| C.E. A5 | 0.482 | 0.528 | 4.1 | 24 | InN | 2.14 | ZnS | 3.56 | 630.4 | 51 | — | 50.9% |
| C.E. A6 | 0.400 | 0.540 | 4.1 | 43 | InN | 2.14 | ZnS | 3.56 | 630.7 | 85 | — | 42.0% |
| C.E. A7 | 0.498 | 0.525 | 5.3 | 22 | CdSe | 2.13 | ZnS | 3.56 | 633.4 | 49 | — | 31.7% |
| C.E. A8 | 0.436 | 0.534 | 5.3 | 28 | CdSe | 2.13 | ZnS | 3.56 | 631.1 | 70 | — | 32.1% |
| C.E. A9 | 0.521 | 0.523 | 4.1 | 39 | InP | 2.15 | — | — | 628.1 | 69 | — | 31.2% |

*M.E. Manufacturing Example,
**C.E. Comparative Example

In Table 1, the vertical column for “500-570 nm/440-460 nm” shows respective numerical values representing respective absorption spectrums of red phosphors prepared for Manufacturing Examples A1 to A15 and Comparative Examples A1 to A9. Specifically, the numerical values are each determined by dividing the local minimum of the absorbance of the absorption spectrum in a range of 500 to 570 nm by the local maximum of the absorbance of the spectrum in a range of 440 to 460 nm.

In the vertical columns for “BG” in the “core” and “shell” columns of Table 1, the band gap of a material for the core and the band gap of a material for the shell are indicated in a unit of “eV”.

From a comparison between the emission spectrums of the red phosphors in FIG. 5 and the transmission spectrum of the red color filter in FIG. 4, it is seen that the emission spectrums of the red phosphors prepared for Manufacturing Examples A1 to A3 show that the red phosphors each emit light in a wavelength region of 590 to 670 nm. From the transmission spectrum of the red color filter in FIG. 4, it is seen that the red color filter transmits 80% or more of the light in a wavelength region of 600 to 680 nm. It is accordingly seen from above that the emission spectrum of each red phosphor and the transmission spectrum of the red color filter have satisfactory wavelength matching therebetween.

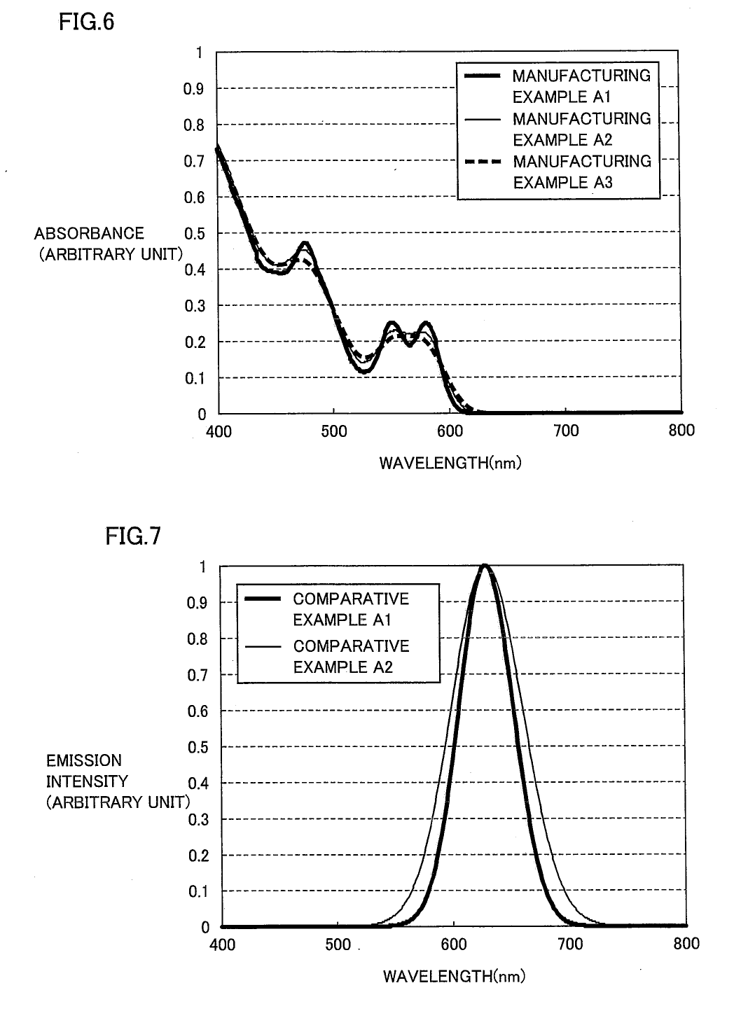

FIG. 6 is a graph of absorption (excitation) spectrums obtained by measuring light absorption (excitation) of respective red phosphors for Manufacturing Examples A1 to A3 with a fluorescence spectrophotometer. In FIG. 6, the vertical axis represents absorbance (in an arbitrary unit) and the horizontal axis represents wavelength (nm). The absorption spectrums here are each obtained by scanning light with an emission intensity at the peak wavelength.

It is seen from respective absorption spectrums of red phosphors for Manufacturing Examples A1 to A3 in FIG. 6 that the red phosphors are each excited by selectively absorbing blue light of 440 to 460 nm. It is also seen from the absorption spectrums that the red phosphors each selectively transmit green light in a wavelength region of 500 to 570 nm in respective emission spectrums of green phosphors prepared for Manufacturing Examples B1 and B2 as described later.

### Comparative Example A1

### Preparation of InP/ZnS Semiconductor Particle Phosphor

A semiconductor particle phosphor having the core/shell structure of InP/ZnS for Comparative Example A1 was prepared by a similar manufacturing method to Manufacturing Example A1 except for the number of times the classification process was repeated for obtaining the core of the semiconductor particles for Manufacturing Example A1.

Specifically, for Manufacturing Example A1, the classification process for the core including the precipitation and settling with the poor solvent and the re-dispersion with the good solvent was repeated ten times. For Comparative Example A1, the classification process including the precipitation and settling with a poor solvent and the re-dispersion with a good solvent was repeated twice to prepare a red phosphor powder for Comparative Example A1. The red phosphor powder obtained for Comparative Example A1 had an average particle size of 4.1 nm and a standard deviation of 27% of the particle size of the InP crystal core.

### Comparative Example A2

### Preparation of InP/ZnS Semiconductor Particle Phosphor

A semiconductor particle phosphor having the core/shell structure of InP/ZnS for Comparative Example A2 was prepared by a similar manufacturing method to Manufacturing Example A1 except that the classification process for obtaining the core of the semiconductor particles for Manufacturing Example A1 was not performed.

Specifically, for Manufacturing Example A1, the classification process for the core including the precipitation and settling with the poor solvent and the re-dispersion with the good solvent was repeated ten times. For Comparative Example A2, a red phosphor powder for Comparative Example A2 was obtained without performing the classification process. The obtained red phosphor powder for Comparative Example A2 had an average particle size of 4.1 nm and a standard deviation of 39% of the particle size of the InP crystal core.

FIG. 7 is a graph showing emission spectrums of respective red phosphors for Comparative Examples A1 and A2. In FIG. 7, the vertical axis represents emission intensity (in an arbitrary unit) and the horizontal axis represents wavelength (nm). From a comparison between the emission spectrums of respective red phosphors for Comparative Examples A1 and A2 in FIG. 7 and the emission spectrums of respective red phosphors for Manufacturing Examples A1 to A3 in FIG. 5, it is seen that the half widths of the emission spectrums of respective red phosphors for Manufacturing Examples A1 to A3 are narrower. It is accordingly seen that a smaller standard deviation of the particle size of the red phosphor provides a smaller half width of the emission spectrum, and the red phosphors for Manufacturing Examples A1 to A3 applied to a semiconductor light emitting apparatus provides a higher color reproducibility of red.

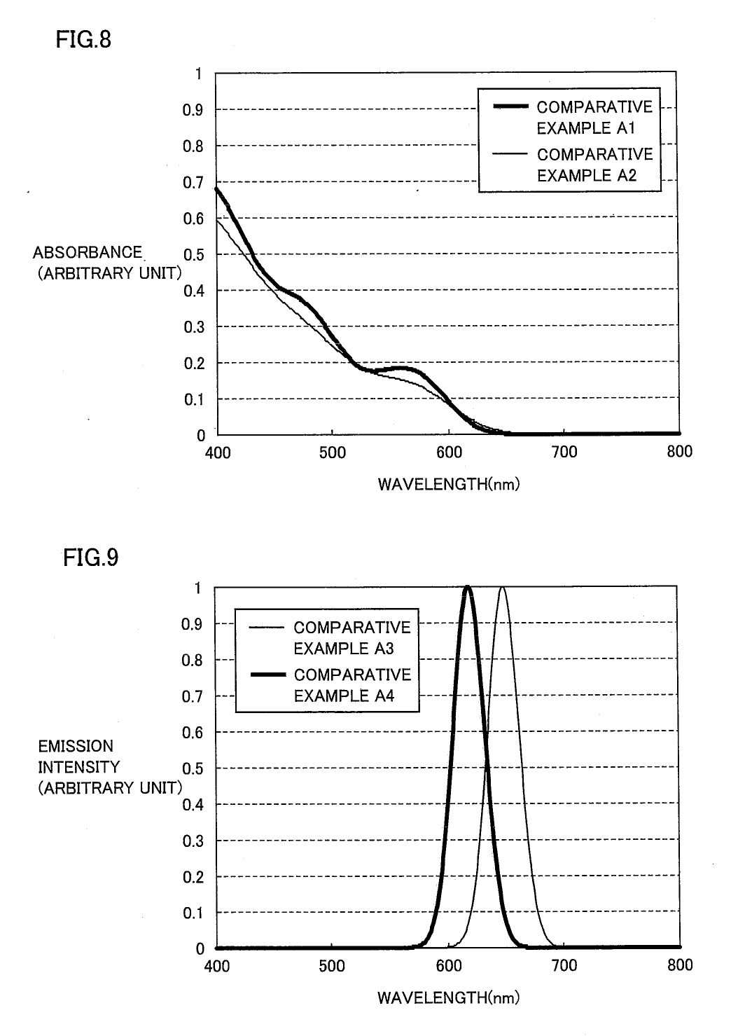

FIG. 8 is a graph showing absorption (excitation) spectrums of respective red phosphors for Comparative Examples A1 and A2. In FIG. 8, the vertical axis represents absorbance (in an arbitrary unit) and the horizontal axis represents wavelength (nm). From a comparison between the absorption spectrums of the red phosphors in FIG. 8 and the absorption spectrums of the red phosphors for Manufacturing Examples A1 to A3 in FIG. 6, it is seen that the absorption spectrums of respective red phosphors for Manufacturing Examples A1 to A3 have a plurality of local maxima and a plurality of local minima, while the absorption spectrums of respective red phosphors for Comparative Examples A1 and A2 have no local maximum and no local minimum. A red phosphor having an absorption spectrum with a plurality of local maxima and a plurality of local minima, like the red phosphors for Manufacturing Examples A1 to A3, selectively absorbs green light with an intensity in a range of 30% or less relative to the maximum intensity of the green light. Further, such a red phosphor selectively transmits green light near the peak wavelength. Accordingly, the color reproducibility and the luminous efficiency of the semiconductor light emitting apparatus can be enhanced.

### Comparative Example A3

### Preparation of InP/ZnS Semiconductor Particle Phosphor

A semiconductor particle phosphor having the core/shell structure of InP/ZnS for Comparative Example A3 was prepared by a similar manufacturing method to Manufacturing Example A2 except for the synthesis temperature condition for obtaining synthesis solution C by heating raw material solution B for Manufacturing Example A2.

Specifically, for Manufacturing Example A2, synthesis solution C was obtained by heating raw material solution B to 350° C. For Comparative Example A3, synthesis solution C was obtained by heating raw material solution B to 370° C. so as to prepare a red phosphor powder for Comparative Example A3. An InP crystal obtained for Comparative Example A3 was directly observed by a TEM, and it was confirmed that the average particle size (diameter) of the InP crystal was 4.2 nm, and the standard deviation of the particle size of the InP core was 11%.

### Comparative Example A4

### Preparation of InP/ZnS Semiconductor Particle Phosphor

A semiconductor particle phosphor having the core/shell structure of InP/ZnS for Comparative Example A4 was prepared by a similar manufacturing method to Manufacturing Example A2 except for the synthesis temperature condition for obtaining synthesis solution C by heating raw material solution B for Manufacturing Example A2.

Specifically, for Manufacturing Example A2, synthesis solution C was obtained by heating raw material solution B to 350° C. For Comparative Example A4, synthesis solution C was obtained by heating raw material solution B to 320° C. so as to prepare a red phosphor powder for Comparative Example A4. An InP crystal obtained for Comparative Example A4 was directly observed by a TEM, and it was confirmed that the average particle size (diameter) of the InP crystal was 4.0 nm, and the standard deviation of the particle size of the InP core was 11%.

FIG. 9 is a graph showing emission spectrums of respective red phosphors for Comparative Examples A3 and A4 when the red phosphors are excited by light with a wavelength of 450 nm. In FIG. 9, the vertical axis represents emission intensity (in an arbitrary unit) and the horizontal axis represents wavelength (nm). From a comparison between the peak wavelength of the emission spectrum of the red phosphor for Manufacturing Example A2 and the emission spectrum of the red phosphor for Comparative Example A3, it is seen that the emission spectrum of Comparative Example A3 in FIG. 9 has a peak wavelength of 647.4 nm and is slightly displaced from the luminosity curve of human eyes, and thus the luminous efficiency of the semiconductor light emitting apparatus using this red phosphor is low. It is also seen that the emission spectrum of Comparative Example A4 in FIG. 9 has a peak wavelength of 618.3 nm and is located on the further inner side on the chromaticity diagram, and thus an image display using this red phosphor has a low color reproducibility of red light.

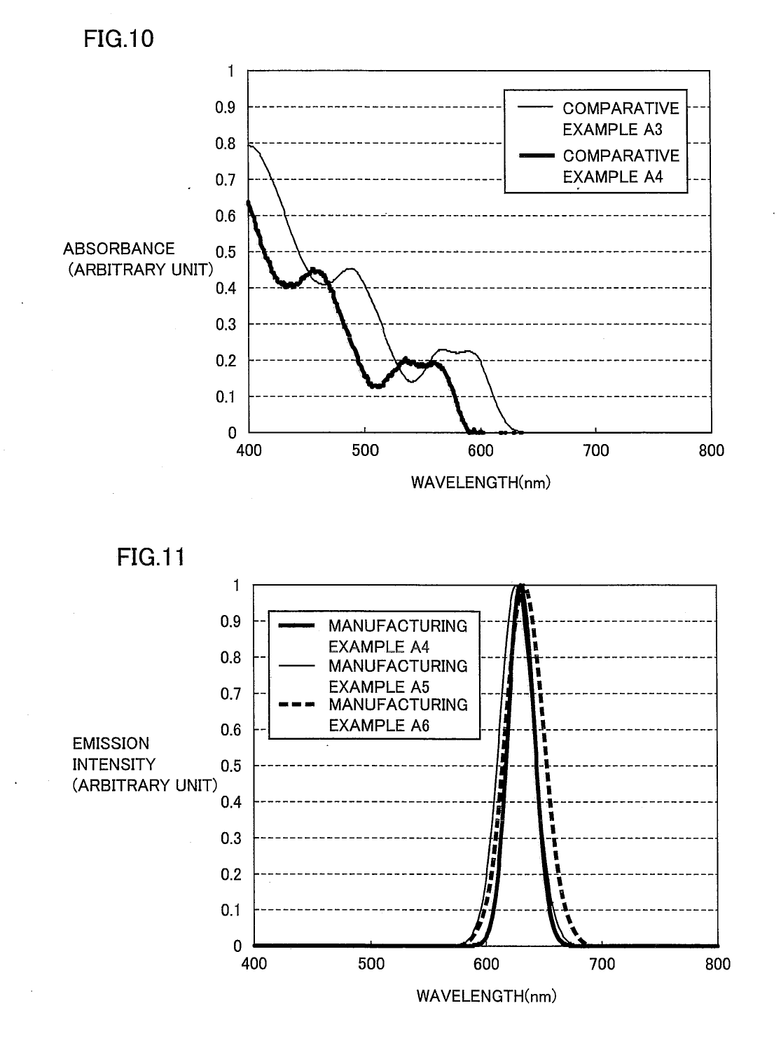

FIG. 10 is a graph showing absorption (excitation) spectrums of respective red phosphors for Comparative Examples A3 and A4. In FIG. 10, the vertical axis represents absorbance (in an arbitrary unit) and the horizontal axis represents wavelength (nm). Like the absorption spectrums in FIG. 10, if an absorption spectrum does not have a local minimum in a wavelength region near the peak wavelength of a green phosphor, red phosphor 13 excessively absorbs light emitted from green phosphor 12. Therefore, the color reproducibility of green light is deteriorated and the luminous efficiency of semiconductor light emitting apparatus 10 is also deteriorated.

Table 1 also shows the chromaticity coordinates of red light, the peak wavelength and the half width of the emission spectrum, characteristics of the absorption spectrum, respective compositions of the core and shell, the average particle size, and the standard deviation of each of the red phosphors obtained for Comparative Examples A1 to A4.

### Manufacturing Examples A4-A6/Comparative Examples A5 and A6

### Manufacturing Example A4

### Preparation of InN/ZnS Semiconductor Particle Phosphor

A semiconductor particle phosphor having the core/shell structure of InN/ZnS for Manufacturing Example A4 was prepared by a similar manufacturing method to Manufacturing Example A1 except that the group V element material added to solution mixture A was replaced with bis(trimethylsilyl)amine and the synthesis temperature condition for obtaining synthesis solution C by heating raw material solution B was changed to 290° C.

Specifically, for Manufacturing Example A1, tris(trimethylcyril)phosphine was used as the group V element material for the core of the red phosphor. For Manufacturing Example A4, 1.6 g (10.0 mmol) of bis(trimethylsilyl)amine was used as the group V element material for the core of the red phosphor. Further, for Manufacturing Example A1, synthesis solution C was obtained by heating raw material solution B to 350° C. For Manufacturing Example A4, synthesis solution C was obtained by heating raw material solution B to 290° C. Solid powder E of the semiconductor particle phosphor for Manufacturing Example A4 was prepared by a similar manufacturing method to Manufacturing Example A1 except for the group V element material for the core and the synthesis temperature condition.

Solid powder E was measured by XRD, and it was confirmed that the diffraction peak was located at the position of InN and thus solid powder E was an InN crystal. Further, solid powder E was directly observed using a TEM, and it was confirmed that the average particle size (diameter) of the InN crystal was 4.1 nm and the standard deviation of the particle size of the InN core was 9%.

A lattice image of the obtained red phosphor for Manufacturing Example A4 was observed through electron beam diffraction using a TEM, and it was found that the semiconductor particle phosphor had the core/shell structure in which the InN core was covered with a ZnS shell. The semiconductor particle phosphor was illuminated by a lamp emitting light with a wavelength of 365 nm. Then, the red phosphor emitted red light.

### Manufacturing Example A5

### Preparation of InN/ZnS Semiconductor Particle Phosphor

A semiconductor particle phosphor having the core/shell structure of InN/ZnS for Manufacturing Example A5 was prepared by a similar manufacturing method to Manufacturing Example A4 except for the number of times the classification process was repeated for obtaining the core of the semiconductor particles for Manufacturing Example A4.

Specifically, for Manufacturing Example A4, the classification process for the core including the precipitation and settling with the poor solvent and the re-dispersion with the good solvent was repeated ten times. For Manufacturing Example A5, the classification process including the precipitation and settling with a poor solvent and the re-dispersion with a good solvent was repeated seven times to prepare a red phosphor powder for Manufacturing Example A5. The red phosphor powder obtained for Manufacturing Example A5 had an average particle size of 4.1 nm and a standard deviation of 13% of the particle size of the InN core.

### Manufacturing Example A6

### Preparation of InN/ZnS Semiconductor Particle Phosphor

A semiconductor particle phosphor having the core/shell structure of InN/ZnS for Manufacturing Example A6 was prepared by a similar manufacturing method to Manufacturing Example A4 except for the number of times the classification process was repeated for obtaining the core of the semiconductor particles for Manufacturing Example A4.

Specifically, for Manufacturing Example A4, the classification process for the core including the precipitation and settling with the poor solvent and the re-dispersion with the good solvent was repeated ten times. For Manufacturing Example A6, the classification process including the precipitation and settling with a poor solvent and the re-dispersion with a good solvent was repeated five times to prepare a red phosphor powder for Manufacturing Example A6. The standard deviation of the particle size of the InN fine crystal core of the red phosphor powder was 15%.

FIG. 11 is a graph showing respective spectrums of light obtained by exciting the red phosphors prepared for Manufacturing Examples A4 to A6 by applying light having a wavelength of 450 nm, using a fluorescence spectrophotometer. In FIG. 11, the vertical axis represents emission intensity (in an arbitrary unit) and the horizontal axis represents wavelength (nm). Table 1 also shows the chromaticity coordinates of red light, the peak wavelength and the half width of the emission spectrum, the composition of the core, the average particle size, and the standard deviation of each of the red phosphors obtained for Manufacturing Examples A4 to A6.

From a comparison between respective emission spectrums of the red phosphors in FIG. 11 and the transmission spectrum of the red color filter in FIG. 4, it is seen that the emission spectrums of the red phosphors prepared for Manufacturing Examples A4 to A6 show that the light is emitted in a wavelength region of 590 to 670 nm. It is apparent from the transmission spectrum of the red color filter in FIG. 4 that the red color filter transmits 80% or more of the light in a wavelength region of 600 to 680 nm. It is accordingly seen that the transmission spectrum of the red color filter and the emission spectrums of respective red phosphors for Manufacturing Examples A4 to A6 have satisfactory wavelength matching therebetween.

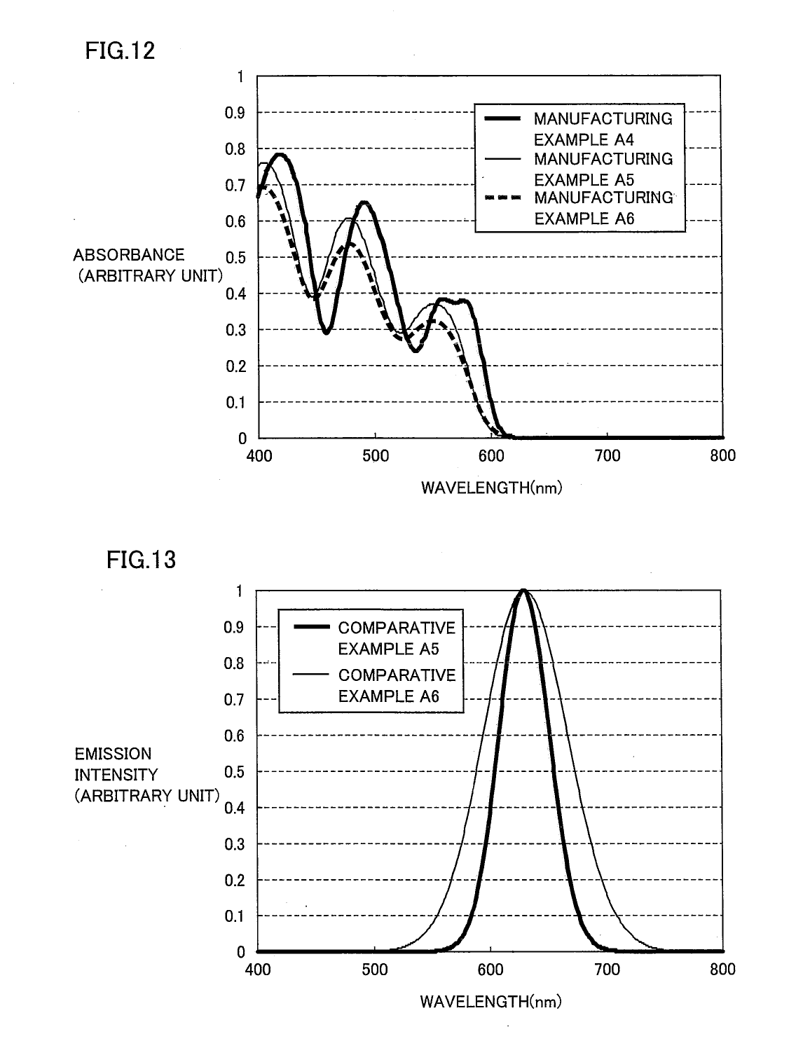

FIG. 12 is a graph showing absorption (excitation) spectrums measured by a fluorescence spectrophotometer for light absorption (excitation) of respective red phosphors for Manufacturing Examples A4 to A6. In FIG. 12, the vertical axis represents absorbance (in an arbitrary unit) and the horizontal axis represents wavelength (nm). The absorption spectrums here were obtained by scanning light with an emission intensity at the peak wavelength.

As seen from the absorption spectrums of respective red phosphors for Manufacturing Example A4 to A6 in FIG. 12, the red phosphors each selectively absorb blue light with a wavelength of 440 to 460 nm and are accordingly excited. From the absorption spectrums of respective red phosphors for Manufacturing Examples A4 to A6, it is also seen that the red phosphors each selectively transmit light in a wavelength region of 500 to 570 nm of the emission spectrums of the green phosphors prepared for Manufacturing Examples B1 and B2 as described later.

### Comparative Example A5

### Preparation of InN/ZnS Semiconductor Particle Phosphor

A semiconductor particle phosphor having the core/shell structure of InN/ZnS for Comparative Example A5 was prepared by a similar manufacturing method to Manufacturing Example A4 except for the number of times the classification process was repeated for obtaining the core of the semiconductor particles for Manufacturing Example A4.

Specifically, for Manufacturing Example A4, the classification process for the core including the precipitation and settling with the poor solvent and the re-dispersion with the good solvent was repeated ten times. For Comparative Example A5, the classification process including the precipitation and settling with a poor solvent and the re-dispersion with a good solvent was repeated twice to prepare a red phosphor powder for Comparative Example A5. The powder of the core in the red phosphor obtained for Comparative Example A5 had an average particle size of 4.1 nm and a standard deviation of 24% of the particle size of the InN core.

### Comparative Example A6

### Preparation of InN/ZnS Semiconductor Particle Phosphor

A semiconductor particle phosphor having the core/shell structure of InN/ZnS for Comparative Example A6 was prepared by a similar manufacturing method to Manufacturing Example A4 except that the classification process for obtaining the core of semiconductor particles for Manufacturing Example A4 was not performed.

Specifically, for Manufacturing Example A4, the classification process for the core including the precipitation and settling with the poor solvent and the re-dispersion with the good solvent was repeated ten times. For Comparative Example A6, the powder of the core in the red phosphor of Comparative Example A6 was prepared without performing the classification process. The powder of the core in the red phosphor obtained for Comparative Example A6 had an average particle size of 4.1 nm and a standard deviation of 43% of the particle size of the InN core.

FIG. 13 is a graph showing emission spectrums of respective red phosphors for Comparative Examples A5 and A6. In FIG. 13, the vertical axis represent emission intensity (in an arbitrary unit) and the horizontal axis represents wavelength (nm). From a comparison between the emission spectrums of respective red phosphors for Comparative Examples A5 and A6 in FIG. 13 and the emission spectrums of respective red phosphors for Manufacturing Examples A4 to A6 in FIG. 11, it is seen that the emission spectrums of respective red phosphors for Manufacturing Examples A4 to A6 each have a smaller half width. Thus, a smaller standard deviation of the particle size of the red phosphor provides a smaller half width of the emission spectrum. It is accordingly seen that a semiconductor light emitting apparatus using the red phosphors for Manufacturing Examples A4 to A6 achieves a higher color reproducibility of red.

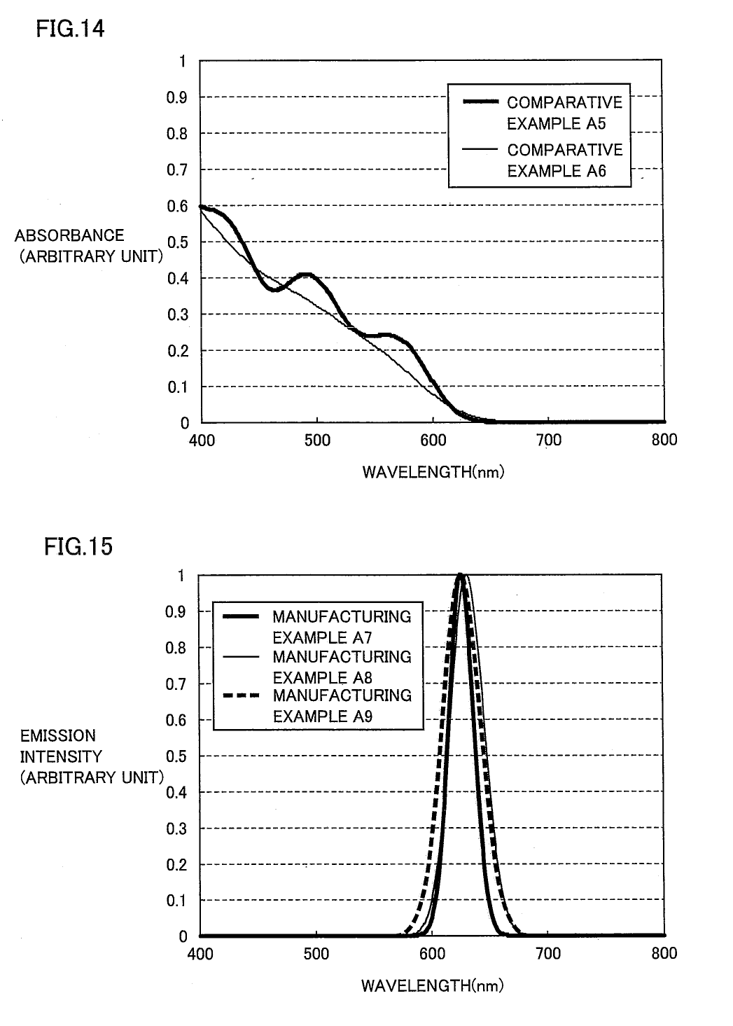

FIG. 14 is a graph showing absorption (excitation) spectrums of respective red phosphors for Comparative Examples A5 and A6. In FIG. 14, the vertical axis represents absorbance (in an arbitrary unit) and the horizontal axis represents wavelength (nm). From a comparison between the absorption spectrums of the red phosphors in FIG. 14 and the absorption spectrums of the red phosphors for Manufacturing Examples A4 to A6 in FIG. 12, it is seen that the absorption spectrums of respective red phosphors for Manufacturing Examples A4 to A6 are each an absorption spectrum having a plurality of local maxima and a plurality of local minima, while the absorption spectrums of respective red phosphors for Comparative Examples A5 and A6 have no local maximum and no local minimum, or have a smaller local maximum or a smaller local minimum. A red phosphor having an absorption spectrum with a plurality of local maxima and a plurality of local minima, like the red phosphors for Manufacturing Examples A4 to A6, can be used to selectively absorb green light in a range of 30% or less of the maximum intensity of the green light. Further, the red phosphor can selectively transmit green light near the peak wavelength. In this way, the color reproducibility of the semiconductor light emitting apparatus can be enhanced, and the luminous efficiency thereof can also be enhanced.

### Manufacturing Examples A7-A9/Comparative Examples A7 and A8

### Manufacturing Example A7

### Preparation of CdSe/ZnS Semiconductor Particle Phosphor

A semiconductor particle phosphor having the core/shell structure of CdSe/ZnS for Manufacturing Example A7 was prepared by a similar manufacturing method to Manufacturing Example A1 except that the group III metal element material added to solution mixture A was replaced with a group II metal element material, the group V element material added thereto was replaced with a group VI element material, and the synthesis temperature condition for obtaining synthesis solution C by heating raw material solution B was changed to 220° C.

Specifically, as the materials for the core in the red phosphor for Manufacturing Example A7, 1.4 g (10.0 mmol) of dimethylcadmium as a group II metal element material, and 4.5 g (10.0 mmol) of trioctylphosphine sulfide as a group VI element material were used.

For Manufacturing Example A1, synthesis solution C was obtained by heating raw material solution B to 350° C. For manufacturing Example A7, synthesis solution C was obtained by heating raw material solution B to 220° C. Solid powder E of the semiconductor particle phosphor for Manufacturing Example A7 was obtained by a similar manufacturing method to Manufacturing Example A1 except for the materials for the core of the red phosphor and the synthesis temperature condition as described above.

Solid powder E was measured by XRD, and it was confirmed that the diffraction peak was located at the position of CdSe and thus solid powder E was a CdSe crystal. Further, solid powder E was directly observed using a TEM, and it was confirmed that the average particle size (diameter) of the CdSe crystal was 5.3 nm and the standard deviation of the particle size of the CdSe core was 6%.

A lattice image of the red phosphor obtained for Manufacturing Example A7 was observed through electron beam diffraction using a TEM, and it was found that the semiconductor particle phosphor had the core/shell structure in which the CdSe core was covered with a ZnS shell. The semiconductor particle phosphor was illuminated by a lamp emitting light with a wavelength of 365 nm. Then, the red phosphor emitted red light.

### Manufacturing Example A8

### Preparation of CdSe/ZnS Semiconductor Particle Phosphor

A semiconductor particle phosphor having the core/shell structure of CdSe/ZnS for Manufacturing Example A8 was prepared by a similar manufacturing method to Manufacturing Example A7 except for the number of times the classification process was repeated for obtaining the core of the semiconductor particles for Manufacturing Example A7.

Specifically, for Manufacturing Example A7, the classification process for the core including the precipitation and settling with the poor solvent and the re-dispersion with the good solvent was repeated ten times. For Manufacturing Example A8, the classification process including the precipitation and settling with a poor solvent and the re-dispersion with a good solvent was repeated seven times to prepare a red phosphor powder for Manufacturing Example A8. The red phosphor powder obtained for Manufacturing Example A8 had an average particle size of 5.3 nm and a standard deviation of 12% of the particle size of the CdSe core.

### Manufacturing Example A9

### Preparation of CdSe/ZnS Semiconductor Particle Phosphor

A semiconductor particle phosphor having the core/shell structure of CdSe/ZnS for Manufacturing Example A9 was prepared by a similar manufacturing method to Manufacturing Example A7 except for the number of times the classification process was repeated for obtaining the core of the semiconductor particles for Manufacturing Example A7.

Specifically, for Manufacturing Example A7, the classification process for the core including the precipitation and settling with the poor solvent and the re-dispersion with the good solvent was repeated ten times. For Manufacturing Example A9, the classification process including the precipitation and settling with a poor solvent and the re-dispersion with a good solvent was repeated five times to prepare a red phosphor powder for Manufacturing Example A9. The red phosphor powder obtained for Manufacturing Example A9 had an average particle size of 5.3 nm and a standard deviation of 15% of the particle size of the CdSe core.

FIG. 15 is a graph showing spectrums of light obtained by exciting the red phosphors prepared for Manufacturing Examples A7 to A9 by applying light having a wavelength of 450 nm, using a fluorescence spectrophotometer. The vertical axis represents emission intensity (in an arbitrary unit) and the horizontal axis represents wavelength (nm).

From a comparison between the emission spectrums of the red phosphors in FIG. 15 and the transmission spectrum of the red color filter in FIG. 4, it is seen that the emission spectrums of the red phosphors prepared for Manufacturing Examples A7 to A9 show that the red phosphors each emit light in a wavelength region of 590 to 660 nm. From the transmission spectrum of the red color filter in FIG. 4, it is seen that the red color filter transmits 80% or more of the light in a wavelength region of 600 to 680 nm. It is accordingly seen from above that the transmission spectrum of the red color filter and the emission spectrums of the red phosphors for Manufacturing Examples A7 to A9 have satisfactory wavelength matching therebetween.

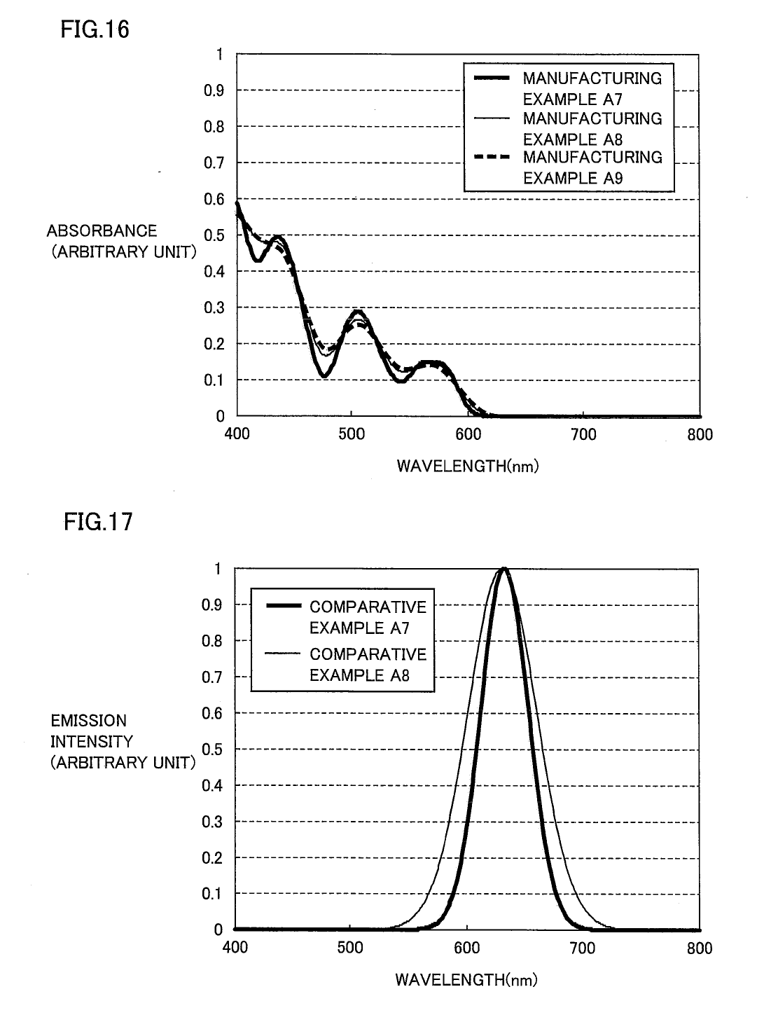

FIG. 16 is a graph showing absorption (excitation) spectrums obtained by measuring light absorption (excitation) of respective red phosphors for Manufacturing Examples A7 to A9, by a fluorescence spectrophotometer. In FIG. 16, the vertical axis represents absorbance (in an arbitrary unit) and the horizontal axis represents wavelength (nm). The absorption spectrums here were each obtained by scanning light with an emission intensity at the peak wavelength.

It is seen from respective absorption spectrums of the red phosphors for Manufacturing Examples A7 to A9 in FIG. 16 that the red phosphors are each excited by selectively absorbing blue light of 440 to 460 nm. It is also seen from the absorption spectrums of the red phosphors for Manufacturing Examples A7 to A9 that the red phosphors each selectively transmit green light in a wavelength region of 500 to 570 nm in respective emission spectrums of green phosphors prepared for Manufacturing Examples B1 and B2 as described later.

### Comparative Example A7

### Preparation of CdSe/ZnS Semiconductor Particle Phosphor

A semiconductor particle phosphor having the core/shell structure of CdSe/ZnS for Comparative Example A7 was prepared by a similar manufacturing method to Manufacturing Example A7 except for the number of times the classification process was repeated for obtaining the core of the semiconductor particles for Manufacturing Example A7.

Specifically, for Manufacturing Example A7, the classification process for the core including the precipitation and settling with the poor solvent and the re-dispersion with the good solvent was repeated ten times. For Comparative Example A7, the classification process including the precipitation and settling with a poor solvent and the re-dispersion with a good solvent was repeated twice to prepare a red phosphor powder for Comparative Example A7. The red phosphor powder obtained for Comparative Example A7 had an average particle size of 5.3 nm and a standard deviation of 22% of the particle size of the CdSe core.

### Comparative Example A8

### Preparation of CdSe/ZnS Semiconductor Particle Phosphor

A semiconductor particle phosphor having the core/shell structure of CdSe/ZnS for Comparative Example A8 was prepared by a similar manufacturing method to Manufacturing Example A7 except that the classification process for obtaining the core of the semiconductor particles for Manufacturing Example A7 was not performed.

Specifically, for Manufacturing Example A7, the classification process for the core including the precipitation and settling with the poor solvent and the re-dispersion with the good solvent was repeated ten times. For Comparative Example A8, a red phosphor powder was prepared without performing the classification process. The red phosphor powder obtained for Comparative Example A8 had an average particle size of 5.3 nm and a standard deviation of 28% of the particle size of the CdSe core.

FIG. 17 is a graph showing emission spectrums of respective red phosphors for Comparative Examples A7 and A8. In FIG. 17, the vertical axis represents emission intensity (in an arbitrary unit) and the horizontal axis represents wavelength (nm). From a comparison between the emission spectrums of the red phosphors in FIG. 17 and the emission spectrums of respective red phosphors for Manufacturing Examples A7 to A9 in FIG. 15, it is seen that the emission spectrums of the red phosphors for Manufacturing Examples A7 to A9 each have a smaller half width. Thus, as the standard deviation of the particle size of a red phosphor is smaller, the half width of the emission spectrum is accordingly smaller. It is therefore clearly seen that a semiconductor light emitting apparatus in which any of the red phosphors for Manufacturing Examples A7 to A9 is used exhibits a higher color reproducibility of red.

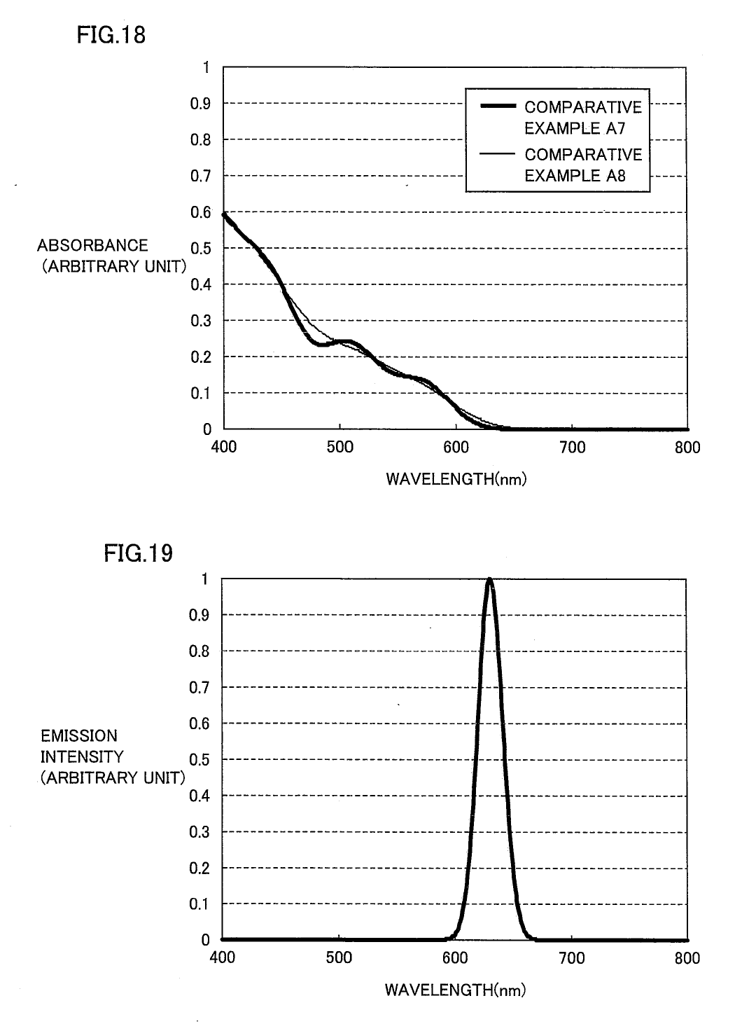

FIG. 18 is a graph showing absorption (excitation) spectrums of respective red phosphors for Comparative Examples A7 and A8. The vertical axis represents absorbance (in an arbitrary unit) and the horizontal axis represents wavelength (nm). From a comparison between the absorption spectrums of the red phosphors in FIG. 18 and the absorption spectrums of the red phosphors for Manufacturing Examples A7 to A9 in FIG. 16, it is seen that the absorption spectrums of the red phosphors for Manufacturing Examples A7 to A9 each have a plurality of local maxima and a plurality of local minima, while the absorption spectrums of the red phosphors for Comparative Examples A7 and A8 are each an absorption spectrum without local maximum and local minimum. A red phosphor having an absorption spectrum with a plurality of local maxima and a plurality of local minima, like the red phosphors for Manufacturing Examples A7 to A9, selectively absorbs green light in a region of 30% or less relative to the maximum intensity of the green light. Further, the red phosphor having the absorption spectrum as described above can selectively transmit green light near the peak wavelength of the green light, and the color reproducibility and the luminous efficiency of the semiconductor light emitting apparatus using the red phosphor can be enhanced.

From a comparison between standard deviations of the particle sizes of the red phosphors for Manufacturing Examples A1 to A9 and the standard deviations of the particle sizes of the red phosphors for Comparative Examples A1 to A8 as shown in Table 1, it is seen that a red phosphor having a standard deviation of the particle size that is within 20% of the average particle size has an emission spectrum with a half width of 45 nm or less. Further, from the absorption spectrums of the red phosphors in FIGS. 6, 8, 10, 12, 14, 16, and 18, it is seen that a red phosphor having an emission spectrum with a half width of 45 nm or less has an absorption spectrum including a plurality of local maxima and a plurality of local minima.

### Manufacturing Examples A10-A14

### Manufacturing Example A10

### Preparation of InGaP/ZnS Semiconductor Particle Phosphor

A semiconductor particle phosphor having the core/shell structure of InGaP/ZnS for Manufacturing Example A10 was prepared by a similar manufacturing method to Manufacturing Example A1 except that a part of the group III metal element material added to solution mixture A for Manufacturing Example A1 was replaced with gallium trichloride.

Specifically, for Manufacturing Example A1, 2.2 g (10.0 mmol) of indium trichloride was used as the group III metal element material for the core of the red phosphor. For Manufacturing Example A10, 1.3 g (6.0 mmol) of indium trichloride and 0.7 g (4.0 mmol) of gallium trichloride were used as the group III metal element material for the core of the red phosphor. Solid powder E of the semiconductor particle phosphor of InGaP for Manufacturing Example A10 was obtained by a similar manufacturing method to Manufacturing Example A1 except for the material for the core of the red phosphor.

Solid powder E was measured by XRD. From the fact that the diffraction peak was located at the position of In_{0.6}Ga_{0.4}P, it was found that solid powder E was an In_{0.6}Ga_{0.4}P crystal. Solid powder E was further observed directly using a TEM, and it was confirmed that the average particle size (diameter) of the In_{0.6}Ga_{0.4}P crystal was 4.1 nm and the standard deviation of the particle size of the In_{0.6}Ga_{0.4}P core was 4.5%.

A lattice image of the red phosphor obtained for Manufacturing Example A10 was observed through electron beam diffraction by a TEM. It was found that the semiconductor particle phosphor had the core/shell structure in which the core of InGaP was covered with a shell of ZnS. The semiconductor particle phosphor was illuminated by a lamp emitting light with a wavelength of 365 nm. Then, the phosphor emitted red light.

FIG. 19 is a graph showing a spectrum obtained by exciting the red phosphor prepared for Manufacturing Example A10 by applying light with a wavelength of 450 nm to the red phosphor, using a fluorescence spectrophotometer. The vertical axis represents emission intensity (in an arbitrary unit) and the horizontal axis represents wavelength (nm). The emission spectrum shown in FIG. 19 has a peak wavelength of 630.5 nm and a half width of 25.4 nm, and the red phosphor has chromaticity coordinates (u′, v′)=(0.540, 0.519).

From a comparison between the emission spectrum of the red phosphor in FIG. 19 and the transmission spectrum of the red color filter in FIG. 4, it is seen that the red phosphor prepared for Manufacturing Example A10 emits light in a wavelength region of 600 to 660 nm in the emission spectrum. Referring to the transmission spectrum of the red color filter in FIG. 4, it is seen that the red color filter transmits 80% or more of the light in a wavelength region of 600 to 680 nm. It is accordingly seen that the transmission spectrum of the red color filter and the emission spectrum of the red phosphor for Manufacturing Example A10 have satisfactory wavelength matching therebetween.

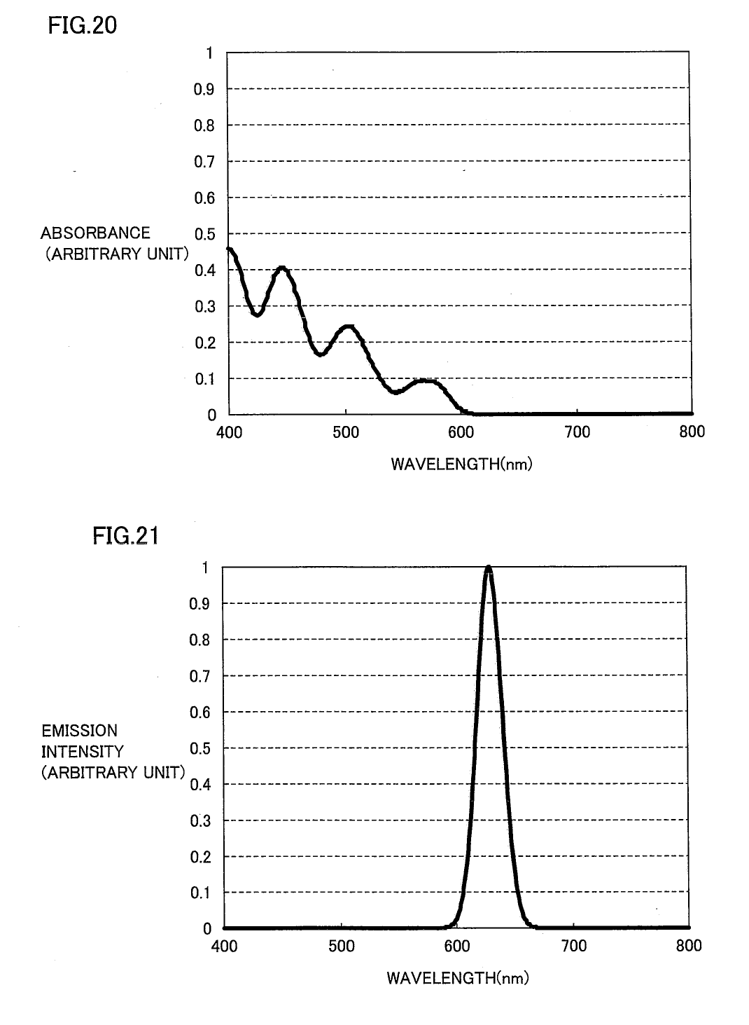

FIG. 20 is a graph showing an absorption (excitation) spectrum obtained by measuring light absorption (excitation) of the red phosphor for Manufacturing Example A10, using fluorescence spectrophotometer. In FIG. 20, the vertical axis represents absorbance (in an arbitrary unit) and the horizontal axis represents wavelength (nm). The absorption (excitation) spectrum was measured by scanning light with an emission intensity at a peak wavelength of 630.5 nm in the emission spectrum.

It is seen from the absorption spectrum of the red phosphor for Manufacturing Example A10 in FIG. 20 that the red phosphor is excited by selectively absorbing blue light of 440 to 460 nm. It is also seen from the absorption spectrum that the red phosphor selectively transmits green light in a wavelength region of 500 to 570 nm in respective emission spectrums of green phosphors prepared for Manufacturing Examples B1 and B2 as described later. Regarding the red phosphor prepared for Manufacturing Example A10, the local minimum of the absorbance in a range of 500 to 570 nm is 14.9% as large as the local maximum of the absorbance in a range of 440 to 460 nm.

### Manufacturing Example A11

### Preparation of InGaN/ZnS Semiconductor Particle Phosphor

A semiconductor particle phosphor having the core/shell structure of InGaN/ZnS for Manufacturing Example A11 was prepared by a similar manufacturing method to Manufacturing Example A1 except that a part of the group III metal element material added to solution mixture A for Manufacturing Example A1 was replaced with gallium trichloride, and the group V element material added thereto for Manufacturing Example A1 was replaced with bis(trimethylsilyl)amine.

Specifically, for Manufacturing Example A1, indium trichloride was used as a group III metal element material for the core of the red phosphor. For Manufacturing Example A11, 1.4 g (6.5 mmol) of indium trichloride and 0.6 g (3.5 mmol) of gallium trichloride were used as the group III metal element material for the core of the red phosphor. Further, for Manufacturing Example A1, tris(trimethylcyril)phosphine was used as a group V element material for the core of the red phosphor. For Manufacturing Example A11, 1.6 g (10.0 mmol) of bis(trimethylsilyl)amine was used as the group V element material for the core of the red phosphor. Solid powder E of the semiconductor particle phosphor for Manufacturing Example A11 was obtained by a similar manufacturing method to Manufacturing Example A1 except for the materials for the core of the red phosphor as described above.

Solid powder E was measured by XRD. From the fact that the diffraction peak was located at the position of In_{0.65}Ga_{0.35}N, it was found that solid powder E was an In_{0.65}Ga_{0.35}N crystal. Solid powder E was further observed directly using a TEM, and it was confirmed that the average particle size of the In_{0.65}Ga_{0.35}N crystal was 2.9 nm and the standard deviation of the particle size of the In_{0.65}Ga_{0.35}N core was 4.4%.

A lattice image of the red phosphor obtained for Manufacturing Example A11 was observed through electron beam diffraction by a TEM. It was found that the semiconductor particle phosphor had the core/shell structure in which the core of InGaN was covered with the shell of ZnS. The semiconductor particle phosphor was illuminated by a lamp emitting light with a wavelength of 365 nm. Then, the phosphor emitted red light.

FIG. 21 is a graph showing a spectrum obtained by exciting the red phosphor prepared for Manufacturing Example A11 by applying light with a wavelength of 450 nm to the red phosphor, using a fluorescence spectrophotometer. The vertical axis in FIG. 21 represents emission intensity (in an arbitrary unit) and the horizontal axis represents wavelength (nm). The emission spectrum shown in FIG. 21 has a peak wavelength of 628.5 nm and a half width of 25.3 nm, and the red phosphor has chromaticity coordinates (u′, v′)=(0.534, 0.520).

From a comparison between the emission spectrum of the red phosphor in FIG. 21 and the transmission spectrum of the red color filter in FIG. 4, it is seen that the red phosphor prepared for Manufacturing Example A11 emits light in a wavelength region of 600 to 660 nm in the emission spectrum. Referring to the transmission spectrum of the red color filter in FIG. 4, it is seen that the red color filter transmits 80% or more of the light in a wavelength region of 600 to 680 nm. It is accordingly seen that the transmission spectrum of the red color filter and the emission spectrum of the red phosphor for Manufacturing Example A11 have satisfactory wavelength matching therebetween.

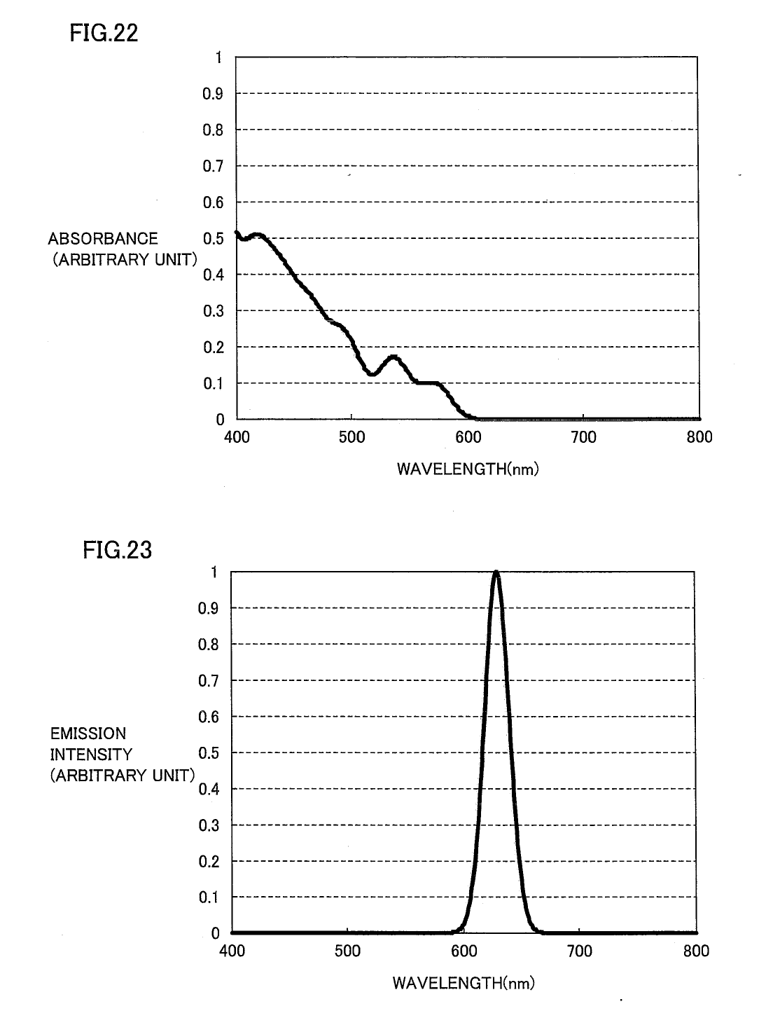

FIG. 22 is a graph showing an absorption (excitation) spectrum obtained by measuring light absorption (excitation) of the red phosphor for Manufacturing Example A11, using a fluorescence spectrophotometer. In FIG. 22, the vertical axis represents absorbance (in an arbitrary unit) and the horizontal axis represents wavelength (nm). The absorption (excitation) spectrum was measured by scanning light with an emission intensity at a peak wavelength of 628.5 nm in the emission spectrum.

It is seen from the absorption spectrum of the red phosphor for Manufacturing Example A11 in FIG. 22 that the red phosphor is excited by selectively absorbing blue light of 440 to 460 nm. It is also seen from the absorption spectrum that the red phosphor selectively transmits green light in a wavelength region of 500 to 570 nm in respective emission spectrums of green phosphors prepared for Manufacturing Examples B1 and B2 as described later. Regarding the red phosphor prepared for Manufacturing Example A11, the local minimum of the absorbance in a range of 500 to 570 nm is 22.3% as large as the local maximum of the absorbance in a range of 440 to 460 nm.

### Manufacturing Example A12

### Manufacture of InGaN/ZnS Semiconductor Particle Phosphor

A semiconductor particle phosphor having the core/shell structure of InGaN/ZnS for Manufacturing Example A12 was prepared by a similar manufacturing method to Manufacturing Example A1 except that a part of the group III metal element material added to solution mixture A for Manufacturing Example A1 was replaced with gallium trichloride, and the group V element material for Manufacturing Example A1 was replaced with bis(trimethylsilyl)amine.

Specifically, for Manufacturing Example A1, indium trichloride was used as a group III metal element material for the core of the red phosphor. For Manufacturing Example A12, 1.3 g (6.0 mmol) of indium trichloride and 0.7 g (4.0 mmol) of gallium trichloride were used as the group III metal element material for the core of the red phosphor. Further, for Manufacturing Example A1, tris(trimethylcyril)phosphine was used as a group V element material for the core of the red phosphor. For Manufacturing Example A12, 1.6 g (10.0 mmol) of bis(trimethylsilyl)amine was used as the group V element material for the core of the red phosphor. Solid powder E of the semiconductor particle phosphor for Manufacturing Example A12 was obtained by a similar manufacturing method to Manufacturing Example A1 except for the materials for the core of the red phosphor.

Solid powder E was measured by XRD. The diffraction peak was located at the position of In_{0.6}Ga_{0.4}N, and it was found that solid powder E was an In_{0.6}Ga_{0.4}N crystal. Solid powder E was further observed directly using a TEM, and it was confirmed that the average particle size of the In_{0.6}Ga_{0.4}N crystal was 2.9 nm and the standard deviation of the particle size of the In_{0.6}Ga_{0.4}N core was 4.4%.

A lattice image of the red phosphor obtained for Manufacturing Example A12 was observed through electron beam diffraction by a TEM. It was found that the semiconductor particle phosphor had the core/shell structure in which the core of InGaN was covered with the shell of ZnS. The semiconductor particle phosphor was illuminated by a lamp emitting light with a wavelength of 365 nm. Then, the phosphor emitted red light.

FIG. 23 is a graph showing a spectrum obtained by exciting the red phosphor prepared for Manufacturing Example A12 by applying light with a wavelength of 450 nm to the red phosphor, using a fluorescence spectrophotometer. The vertical axis in FIG. 23 represents emission intensity (in an arbitrary unit) and the horizontal axis represents wavelength (nm). The emission spectrum shown in FIG. 23 has a peak wavelength of 628.5 nm and a half width of 25.1 nm, and the red phosphor has chromaticity coordinates (u′, v′)=(0.534, 0.520).

From a comparison between the emission spectrum of the red phosphor in FIG. 23 and the transmission spectrum of the red color filter in FIG. 4, it is seen that the red phosphor prepared for Manufacturing Example A12 emits light in a wavelength region of 600 to 660 nm in the emission spectrum. Referring to the transmission spectrum of the red color filter in FIG. 4, it is seen that the red color filter transmits 80% or more of the light in a wavelength region of 600 to 680 nm. It is accordingly seen that the transmission spectrum of the red color filter and the emission spectrum of the red phosphor for Manufacturing Example A12 have satisfactory wavelength matching therebetween.

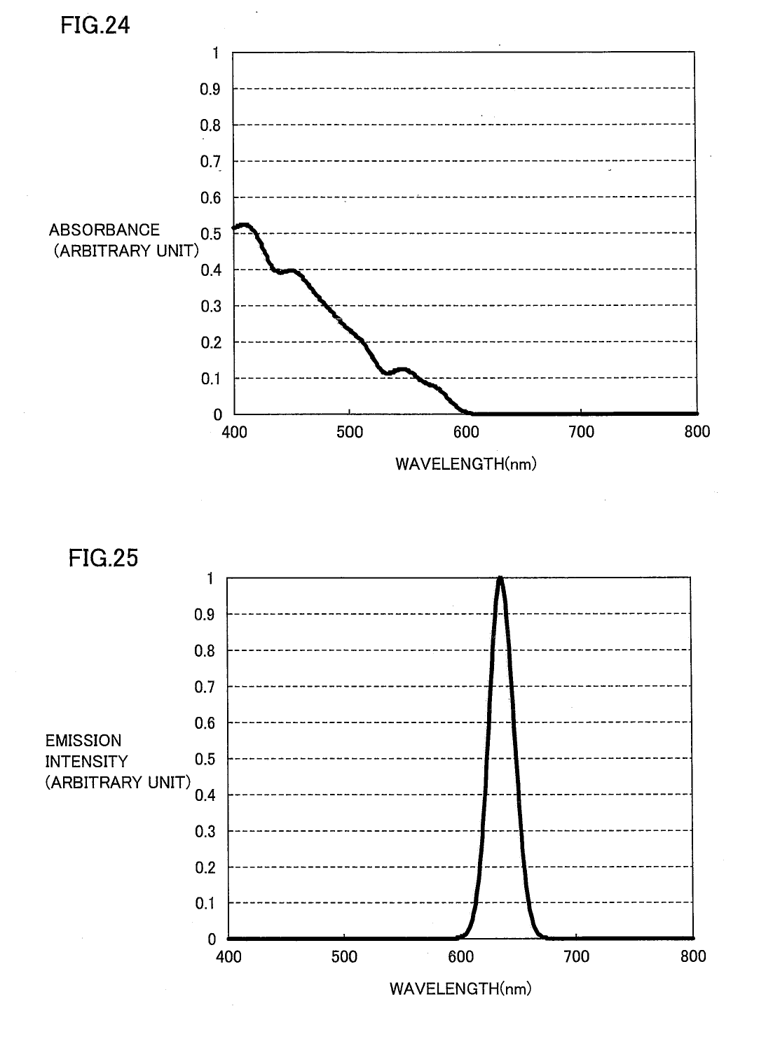

FIG. 24 is a graph showing an absorption (excitation) spectrum obtained by measuring light absorption (excitation) of the red phosphor for Manufacturing Example A12, using a fluorescence spectrophotometer. In FIG. 24, the vertical axis represents absorbance (in an arbitrary unit) and the horizontal axis represents wavelength (nm). The absorption (excitation) spectrum was measured by scanning light with an emission intensity at a peak wavelength of 628.5 nm in the emission spectrum.

It is seen from the absorption spectrum of the red phosphor for Manufacturing Example A12 in FIG. 24 that the red phosphor is excited by selectively absorbing blue light of 440 to 460 nm. It is also seen from the absorption spectrum of the red phosphor for Manufacturing Example A12 that the red phosphor selectively transmits green light in a wavelength region of 500 to 570 nm in respective emission spectrums of green phosphors prepared for Manufacturing Examples B1 and B2 as described later. Regarding the red phosphor prepared for Manufacturing Example A12, the local minimum of the absorbance in a range of 500 to 570 nm is 24.1% as large as the local maximum of the absorbance in a range of 440 to 460 nm.

### Manufacturing Example A13

### Preparation of InGaN/ZnS Semiconductor Particle Phosphor

A semiconductor particle phosphor having the core/shell structure of InGaN/ZnS for Manufacturing Example A13 was prepared by a similar manufacturing method to Manufacturing Example A1 except that a part of the group III metal element material added to solution mixture A for Manufacturing Example A1 was replaced with gallium trichloride, and the group V element material for Manufacturing Example A was replaced with bis(trimethylsilyl)amine.

Specifically, for Manufacturing Example A1, indium trichloride was used as a group III metal element material for the core of the red phosphor. For Manufacturing Example A13, 2.0 g (9.0 mmol) of indium trichloride and 0.2 g (1.0 mmol) of gallium trichloride were used as the group III metal element material for the core of the red phosphor. Further, for Manufacturing Example A1, tris(trimethylcyril)phosphine was used as a group V element material for the core of the red phosphor. For Manufacturing Example A13, 1.6 g (10.0 mmol) of bis(trimethylsilyl)amine was used as the group V element material for the core of the red phosphor. Solid powder E of the semiconductor particle phosphor for Manufacturing Example A13 was obtained by a similar manufacturing method to Manufacturing Example A1 except for the materials for the core of the red phosphor.

Solid powder E was measured by XRD. The diffraction peak was located at the position of In_{0.9}Ga_{0.1}N, and it was found that solid powder E was In_{0.9}Ga_{0.1}N crystal. Solid powder E was further observed directly using a TEM, and it was confirmed that the average particle size of the In_{0.9}Ga_{0.1}N crystal was 2.1 nm and the standard deviation of the particle size of the In_{0.9}Ga_{0.1}N core was 4.5%.

A lattice image of the red phosphor obtained for Manufacturing Example A13 was observed through electron beam diffraction by a TEM. It was found that the semiconductor particle phosphor had the core/shell structure in which the core of InGaN was covered with the shell of ZnS. The semiconductor particle phosphor was illuminated by a lamp emitting light with a wavelength of 365 nm. Then, the phosphor emitted red light.

FIG. 25 is a graph showing a spectrum obtained by exciting the red phosphor prepared for Manufacturing Example A13 by applying light with a wavelength of 450 nm to the red phosphor, using a fluorescence spectrophotometer. The vertical axis in FIG. 25 represents emission intensity (in an arbitrary unit) and the horizontal axis represents wavelength (nm). The emission spectrum shown in FIG. 25 has a peak wavelength of 636.4 nm and a half width of 25.4 nm, and the red phosphor has chromaticity coordinates (u′, v′)=(0.556, 0.517).

From a comparison between the emission spectrum of the red phosphor in FIG. 25 and the transmission spectrum of the red color filter in FIG. 4, it is seen that the red phosphor prepared for Manufacturing Example A13 emits light in a wavelength region of 600 to 660 nm in the emission spectrum. Referring to the transmission spectrum of the red color filter in FIG. 4, it is seen that the red color filter transmits 80% or more of the light in a wavelength region of 600 to 680 nm. It is accordingly seen that the transmission spectrum of the red color filter and the emission spectrum of the red phosphor for Manufacturing Example A13 have satisfactory wavelength matching therebetween.

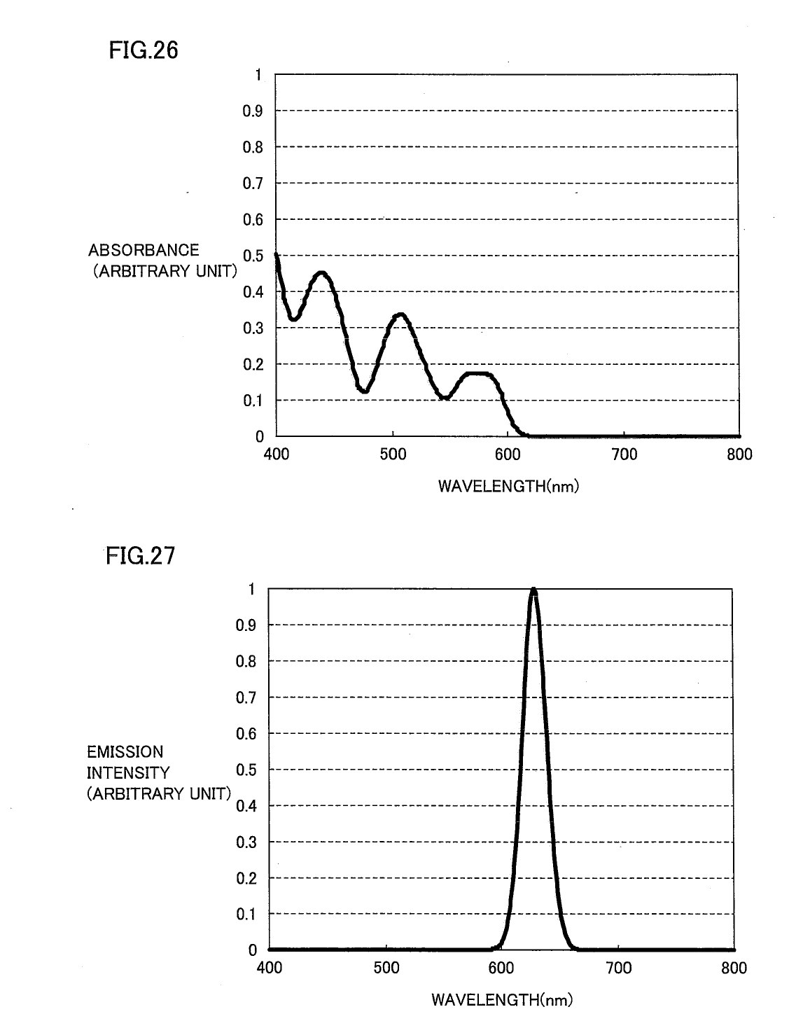

FIG. 26 is a graph showing an absorption (excitation) spectrum obtained by measuring light absorption (excitation) of the red phosphor for Manufacturing Example A13, using a fluorescence spectrophotometer. In FIG. 26, the vertical axis represents absorbance (in an arbitrary unit) and the horizontal axis represents wavelength (nm). The absorption (excitation) spectrum was measured by scanning light with an emission intensity at a peak wavelength of 636.4 nm in the emission spectrum.

It is seen from the absorption spectrum of the red phosphor for Manufacturing Example A13 in FIG. 26 that the red phosphor is excited by selectively absorbing blue light of 440 to 460 nm. It is also seen from the absorption spectrum of the red phosphor for Manufacturing Example A13 that the red phosphor selectively transmits green light in a wavelength region of 500 to 570 nm in respective emission spectrums of green phosphors prepared for Manufacturing Examples B1 and B2 as described later. Regarding the red phosphor prepared for Manufacturing Example A13, the local minimum of the absorbance in a range of 520 to 540 nm is 23.4% as large as the local maximum of the absorbance in a range of 440 to 460 nm.

### Manufacturing Example A14

### Preparation of ZnCdSe/ZnS Semiconductor Particle Phosphor

A semiconductor particle phosphor having the core/shell structure of ZnCdSe/ZnS for Manufacturing Example A14 was prepared by a similar manufacturing method to Manufacturing Example A1 except that the group III metal element material added to solution mixture A was replaced with two different group II metal element materials, and the group V element material was replaced with a group VI element material.

Specifically, for Manufacturing Example A14, 0.14 g (1.0 mmol) of dimethylcadmium and 1.1 g (9.0 mmol) of diethylzinc were used as the group II metal element materials and 4.5 g (10.0 mmol) of trioctylphosphine sulfide was used as a group VI element material, as materials for the core of the red phosphor. Solid powder E of the semiconductor particle phosphor for Manufacturing Example A14 was obtained by a similar manufacturing method to Manufacturing Example A1 except for the materials for the core of the red phosphor.

Solid powder E was measured by XRD. The diffraction peak was located at the position of Zn_{0.1}Cd_{0.9}Se, and it was found that solid powder E was a Zn_{0.1}Cd_{0.9}Se crystal. Solid powder E was further observed directly using a TEM, and it was confirmed that the average particle size of the Zn_{0.1}Cd_{0.9}Se crystal was 5.4 nm and the standard deviation of the particle size of the Zn_{0.1}Cd_{0.9}Se core was 4.1%.

A lattice image of the red phosphor obtained for Manufacturing Example A14 was observed through electron beam diffraction by a TEM. It was found that the semiconductor particle phosphor had the core/shell structure in which the core of ZnCdSe was covered with the shell of ZnS. The semiconductor particle phosphor was illuminated by a lamp emitting light with a wavelength of 365 nm. Then, the phosphor emitted red light.

FIG. 27 is a graph showing a spectrum obtained by exciting the red phosphor prepared for Manufacturing Example A14 by applying light with a wavelength of 450 nm to the red phosphor, using a fluorescence spectrophotometer. The vertical axis in FIG. 27 represents emission intensity (in an arbitrary unit) and the horizontal axis represents wavelength (nm).

From a comparison between the emission spectrum of the red phosphor in FIG. 27 and the transmission spectrum of the red color filter in FIG. 4, it is seen that the emission spectrum of the red phosphor prepared for Manufacturing Example A14 and the transmission spectrum of the red phosphor have satisfactory wavelength matching therebetween. The emission spectrum shown in FIG. 27 has a peak wavelength of 629.2 nm and a half width of 24.3 nm, and the red phosphor has chromaticity coordinates (u′, v′)=(0.536, 0.520).

Further, from a comparison between the emission spectrum of the red phosphor in FIG. 27 and the transmission spectrum of the red color filter in FIG. 4, it is seen that the red phosphor prepared for Manufacturing Example A14 emits light in a wavelength region of 600 to 660 nm in the emission spectrum. Referring to the transmission spectrum of the red color filter in FIG. 4, it is seen that the red color filter transmits 80% or more of the light in a wavelength region of 600 to 680 nm. It is accordingly seen that the transmission spectrum of the red color filter and the emission spectrum of the red phosphor for Manufacturing Example A14 have satisfactory wavelength matching therebetween.

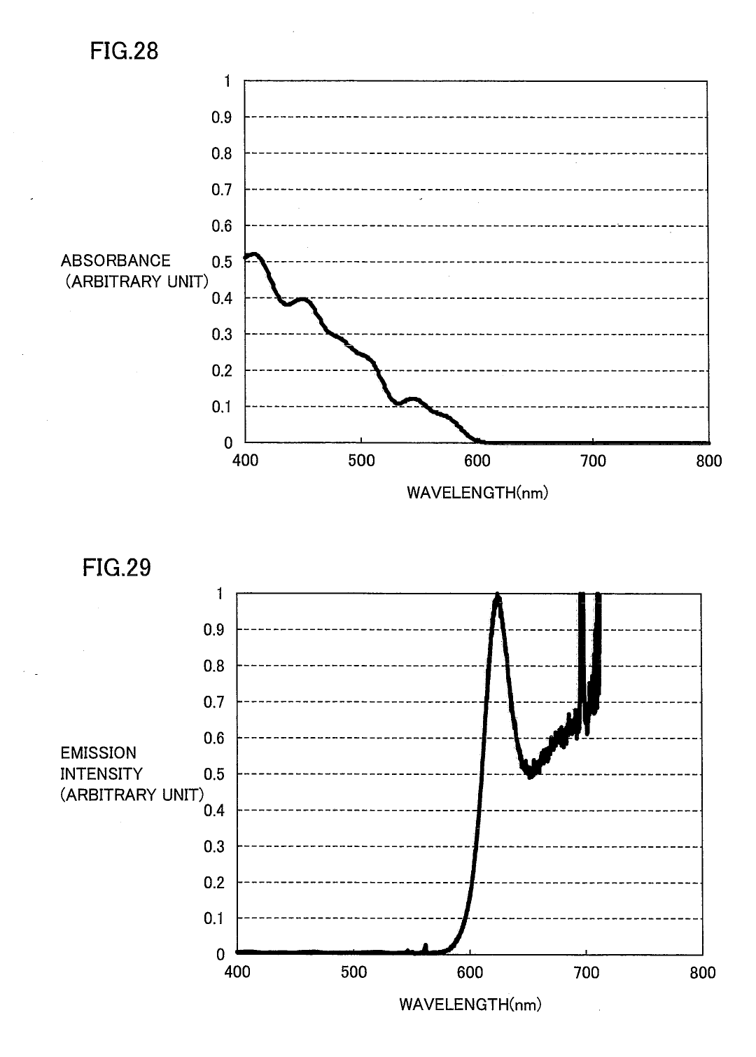

FIG. 28 is a graph showing an absorption (excitation) spectrum obtained by measuring light absorption (excitation) of the red phosphor for Manufacturing Example A14, using a fluorescence spectrophotometer. In FIG. 28, the vertical axis represents absorbance (in an arbitrary unit) and the horizontal axis represents wavelength (nm). The absorption (excitation) spectrum was measured by scanning light with an emission intensity at a peak wavelength of 629.2 nm in the emission spectrum.

It is seen from the absorption spectrum of the red phosphor for Manufacturing Example A14 in FIG. 28 that the red phosphor is excited by selectively absorbing blue light of 440 to 460 nm. It is also seen from the absorption spectrum of the red phosphor for Manufacturing Example A14 that the red phosphor selectively transmits green light in a wavelength region of 500 to 570 nm in respective emission spectrums of green phosphors prepared for Manufacturing Examples B1 and B2 as described later. Regarding the red phosphor prepared for Manufacturing Example A14, the local minimum of the absorbance in a range of 500 to 570 nm is 18.8% as large as the local maximum of the absorbance in a range of 440 to 460 nm.

Referring to Table 1, in the column of “(local minimum of absorbance in) 500-570 nm/(local maximum of absorbance in) 440-460 nm”, the red phosphors for Manufacturing Examples A1 to A3 each having the core composition of InP are compared with the red phosphor for Manufacturing Example A10 having the core composition of InGaP. The red phosphor for Manufacturing Example A10 has a relatively smaller value that is determined by dividing the local minimum of the absorbance in 500 to 570 nm by the local maximum of the absorbance in 440 to 460 nm. It is seen from above that the red phosphor for Manufacturing Example A10 tends to absorb less light emitted from a green phosphor. It is accordingly found that, for a core of a red phosphor of a ternary mixed crystal such as InGaP, control of the absorption spectrum is easier as compared with a core of a red phosphor of a binary compound such as InP.

Likewise, in the column of “(local minimum of absorbance in) 500-570 nm/(local maximum of absorbance in) 440-460 nm” of Table 1, the red phosphors for Manufacturing Examples A4 to A6 each having the core composition of InN are compared with the red phosphors for Manufacturing Examples A11 to A13 each having the core composition of InGaN. It is also seen that control of the absorption spectrum is easier for a red phosphor having a core of a ternary mixed crystal such as InGaN, as compared with a red phosphor having a core of a binary compound such as InN. Further, the red phosphors for Manufacturing Examples A7 to A9 each having the core composition of CdSe and the red phosphor for Manufacturing Example A14 having the core composition of ZnCdSe are compared with each other. It is also seen that control of the absorption spectrum is easier for a red phosphor having a core of a ternary mixed crystal such as ZnCdSe, as compared with a red phosphor having a core of a binary compound such as CdSe.

As clearly seen from above, in terms of control of the absorption spectrum of the red phosphor, it is more preferable to use a ternary mixed crystal, rather than a binary compound.

### Manufacturing Example A15, Comparative Example A9

### Manufacturing Example A15

### Preparation of InP Semiconductor Particle Phosphor

A semiconductor particle phosphor having the single core structure of InP for Manufacturing Example A15 was prepared by a similar manufacturing method to Manufacturing Example A2 except that the process for growing the shell for Manufacturing Example A2 was not included. Specifically, solid powder E of semiconductor particles with the single core structure was used as it is as the red phosphor powder for Manufacturing Example A15, without growing a shell for solid powder E. The InP crystal obtained for Manufacturing Example A15 was directly observed by a TEM, and it was confirmed that the InP crystal had an average particle size (diameter) of 4.1 nm and a standard deviation of the particle size of the InP core of 11%.

FIG. 29 is a graph showing an emission spectrum of the red phosphor for Manufacturing Example A15, excited by applying light with a wavelength of 450 nm to the red phosphor. In FIG. 29, the vertical axis represents emission intensity (in an arbitrary unit) and the horizontal axis represents wavelength (nm). The emission peak intensity of the InP semiconductor particle phosphor for Manufacturing Example A15 shown in FIG. 29 is smaller than the emission peak intensity of the InP/ZnS semiconductor particle phosphor for Manufacturing Example A2, by one or more order of magnitude. It is clearly seen from above that a semiconductor particle phosphor of the core/shell structure has a higher luminous efficiency than a semiconductor particle phosphor of the single core structure. The factor of this difference in luminous efficiency is considered as lack of electron confinement effect provided by the shell, in the case of the semiconductor particle phosphor of the single core structure.

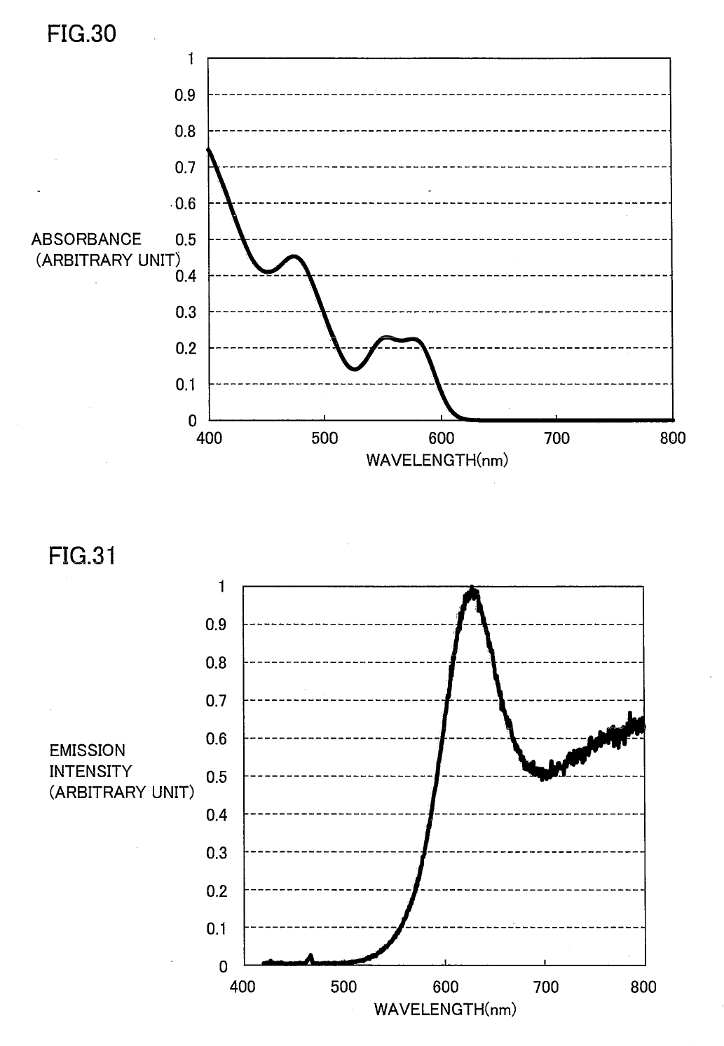

FIG. 30 is a graph showing an absorption (excitation) spectrum of the red phosphor for Manufacturing Example A15. In FIG. 30, the vertical axis represents absorbance (in an arbitrary unit) and the horizontal axis represents wavelength (nm).

### Comparative Example A9

### Preparation of InP Semiconductor Particle Phosphor

A semiconductor particle phosphor of the single core structure of InP for Comparative Example A9 was prepared by a similar manufacturing method to Comparative Example A2 except that the process for growing the shell for Comparative Example A2 was not included. Specifically, for Comparative Example A9, solid powder E of semiconductor particles with the single core structure was used as it is as a red phosphor powder without growing a shell for solid powder E. The InP crystal obtained for Comparative Example A9 was directly observed by a TEM, and it was confirmed that the InP crystal had an average particle size (diameter) of 4.1 nm and a standard deviation of the particle size of the InP core of 39%.

FIG. 31 is a graph showing an emission spectrum of the red phosphor for Comparative Example A9, excited by applying light with a wavelength of 450 nm to the red phosphor. In FIG. 31, the vertical axis represents emission intensity (in an arbitrary unit) and the horizontal axis represents wavelength (nm). The emission peak intensity of the InP semiconductor particle phosphor for Comparative Example A9 shown in FIG. 31 is smaller than the emission peak intensity of the InP/ZnS semiconductor particle phosphor for Comparative Example A2, by one or more order of magnitude. It is clearly seen from above that a semiconductor particle phosphor of the core/shell structure has a higher luminous efficiency than a semiconductor particle phosphor of the single core structure. The factor of this difference in luminous efficiency is considered as lack of electron confinement effect provided by the shell, in the case of the semiconductor particle phosphor of the single core structure.

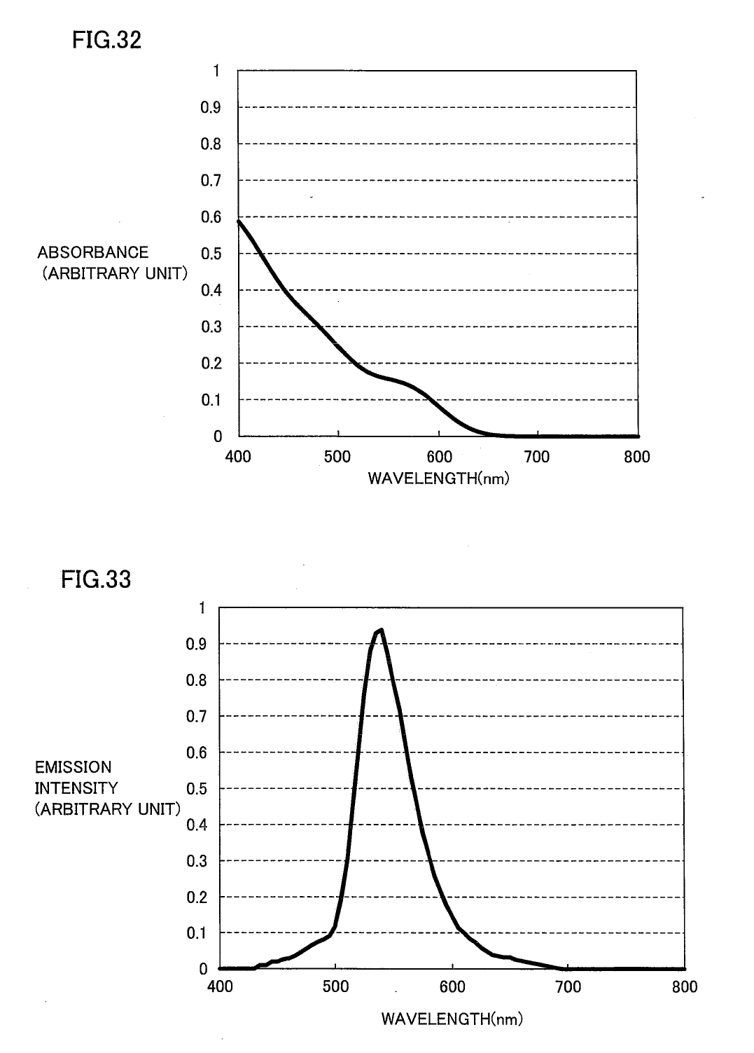

FIG. 32 is a graph showing an absorption (excitation) spectrum of the red phosphor for Comparative Example A9. In FIG. 32, the vertical axis represents absorbance (in an arbitrary unit) and the horizontal axis represents wavelength (nm).

<Preparation of Green Phosphor>

Respective green phosphors for Manufacturing Examples B1 and B2 were prepared through the following procedures.

### Manufacturing Example B1

### Preparation of Eu Activated β-SiAlON Phosphor

First, 95.82% by mass of α-type silicon nitride powder, 3.37% by mass of aluminum nitride powder and 0.81% by mass of europium oxide powder were weighed out to obtain the composition with this ratio. The powders were put in a mortar of sintered silicon nitride, and mixed for 10 minutes or more using a pestle of sintered silicon nitride to obtain a powder aggregate. Next, the powder aggregate was put by free fall in a crucible of boron nitride of 20 mm in diameter and 20 mm in height.

Then, the crucible was set in a pressurized electric furnace of graphite resistance heating type, nitrogen having a purity of 99.999% by volume was introduced, and the pressure was adjusted to 1 MPa. The pressurized electric furnace was heated at a rate of 500° C. per hour to 1900° C. The temperature of 1900° C. was kept for eight hours. A sample of phosphor was thus produced. Then, the phosphor sample was ground using a mortar of agate to obtain a phosphor powder.

The phosphor powder was then analyzed by powder x-ray diffraction using Cu Kα radiation. All charts obtained from the phosphor powder showed a β-type SiAlON structure. The phosphor was illuminated by a lamp emitting light with a wavelength of 365 nm, and the phosphor emitted green light. It was made clear from above that the phosphor powder obtained in the above-described manner was a green phosphor.

FIG. 33 is a graph showing an emission spectrum of the green phosphor obtained for Manufacturing Example B1 when excited by light of 450 nm. In FIG. 33, the vertical axis represents emission intensity (in an arbitrary unit) and the horizontal axis represents wavelength (nm). The emission spectrum of the green phosphor shown in FIG. 33 was also measured by a fluorescence spectrophotometer which was used for measurement of the red phosphors. The emission spectrum shown in FIG. 33 has a peak wavelength of 540 nm and a half width of 55 nm, and the chromaticity coordinates of the green phosphor are (u′, v′)=(0.129, 0.575).

### Manufacturing Example B2

### Preparation of Eu Activated β-SiAlON

First, 93.59% by mass of metal Si powder, 5.02% by mass of aluminum nitride powder and 1.39% by mass of europium oxide powder having been sifted through a sieve of 45 μm were weighed out to obtain the composition with this ratio. The powders were put in a mortar of sintered silicon nitride, and mixed for 10 minutes or more using a pestle of sintered silicon nitride to obtain a powder aggregate. Next, the powder aggregate was put by free fall in a crucible of boron nitride of 20 mm in diameter and 20 mm in height.

The crucible was set in a pressurized electric furnace of graphite resistance heating type, and the pressure of a firing atmosphere was adjusted to a vacuum using a diffusion pump. The pressurized electric furnace was heated at a rate of 500° C. per hour from room temperature to 800° C. When the temperature reached 800° C., nitrogen having a purity of 99.999% by volume was introduced, the pressure was adjusted to 0.5 MPa, and the temperature was further increased at a rate of 500° C. per hour to 1300° C.

The temperature was increased by 1° C. per minute to 1600° C., and the temperature of 1600° C. was kept for eight hours. A phosphor sample was accordingly produced. Then, the phosphor sample was put in a mortar of agate and ground to obtain a phosphor powder. The phosphor powder was heated again in a similar way to the above-described one.

Specifically, the phosphor powder was put by free fall in a crucible of boron nitride of 20 mm in diameter and 20 mm in height. The crucible was set in a pressurized electric furnace of graphite resistance heating type. A diffusion pump was used to adjust the pressure of the firing atmosphere to a vacuum. The temperature was increased at a rate of 500° C. per hour from room temperature to 800° C. When the temperature reached 800° C., nitrogen having a purity of 99.999% by volume was introduced and the pressure was adjusted to 1 MPa. After this, the temperature of the pressurized electric furnace was increased at a rate of 500° C. per hour from 800° C. to 1900° C., and the temperature of 1900° C. was kept for eight hours to produce a phosphor sample. The phosphor sample was put in a mortar of agate and ground into powder. In this way, the phosphor powder was obtained.

The phosphor powder was then analyzed by powder x-ray diffraction using Cu Kα radiation. All charts obtained from the phosphor powder had a β-type SiAlON structure. The phosphor was illuminated by a lamp emitting light with a wavelength of 365 nm, and the phosphor emitted green light. It was thus made clear that the phosphor powder obtained in the above-described manner was a green phosphor.

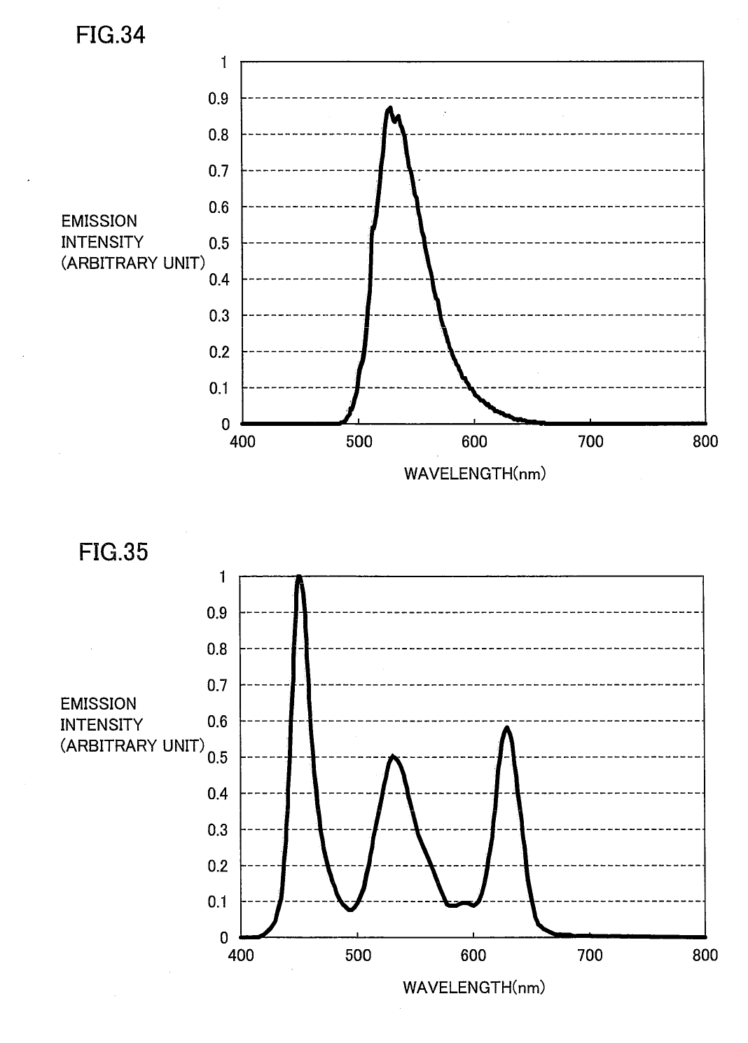

FIG. 34 is a graph showing an emission spectrum of the green phosphor obtained for Manufacturing Example B2 when excited by light of 450 nm. In FIG. 34, the vertical axis represents emission intensity (in an arbitrary unit) and the horizontal axis represents wavelength (nm). The emission spectrum of the green phosphor shown in FIG. 34 was also measured by the same fluorescence spectrophotometer as the one used for measuring the red phosphors and under the same conditions. The emission spectrum shown in FIG. 34 has a peak wavelength of 528 nm and a half width of 51 nm, and the chromaticity coordinates of the green phosphor are (u′, v′)=(0.110, 0.577).

<Production of Semiconductor Light Emitting Apparatus>

### Example 1

### Semiconductor Light Emitting Apparatus

First, the red phosphor prepared for Manufacturing Example A1 and the green phosphor prepared for Manufacturing Example B1 were mixed at a weight ratio according to the column of “green phosphor/red phosphor (wt)” in Table 2 below, namely the green phosphor and the red phosphor were mixed at a weight ratio of 3.87:1 to obtain a phosphor mixture.

Next, according to the column of “silicone resin/phosphor mixture (wt)” in Table 2, a silicone resin and the phosphor mixture were mixed at a weight ratio of 26.68:1, and the red phosphor and the green phosphor were dispersed in the silicone resin to obtain a molded resin.

The molded resin obtained in the above-described manner was used to seal a semiconductor light emitting device having an emission peak wavelength of 450 nm, and a semiconductor light emitting apparatus for Example 1 having the structure shown in FIG. 2 was produced. An emission spectrum of the semiconductor light emitting apparatus for Example 1 was measured by an emission measurement system (product name: MCPD-2000 (manufactured by Otsuka Electronics Co., Ltd.)).

FIG. 35 is a graph showing an emission spectrum of the semiconductor light emitting apparatus produced for Example 1. In FIG. 35, the vertical axis represents emission intensity (in an arbitrary unit) and the horizontal axis represents wavelength (nm). The emission spectrum shown in FIG. 35 is adjusted such that a white point substantially represents white with a color temperature of 10000 K when an image display is structured using the semiconductor light emitting apparatus for Example 1.

### Examples 2-19

### Semiconductor Light Emitting Apparatus

Respective semiconductor light emitting apparatuses for Examples 2 to 19 were produced similarly to Example 1. Specifically, the red phosphors prepared for Manufacturing Example A2 to A15 and the green phosphors prepared for Manufacturing Examples B1 and B2 were combined according to the combinations specified in Table 2, and the red phosphor and the green phosphor were mixed at a weight ratio according to the column of “green phosphor/red phosphor (wt)” in Table 2. Respective phosphor mixtures were thus obtained.

The phosphor mixtures were each mixed with a silicone resin at a weight ratio according to the column of “silicone resin/phosphor mixture (wt)” in Table 2, and the red phosphor and green phosphor were dispersed in the silicone resin to obtain a molded resin component.

The molded resins obtained according to respective combinations specified in Table 2 were each used to seal a semiconductor light emitting device having an emission spectrum with a peak wavelength of 450 nm. Accordingly, respective semiconductor light emitting apparatuses for Examples 2 to 19 having the structure shown in FIG. 2 were produced. An emission measurement system similar to Example 1 was used to measure respective emission spectrums of the semiconductor light emitting apparatuses for Examples 4, 7, 10, 11, and 14.

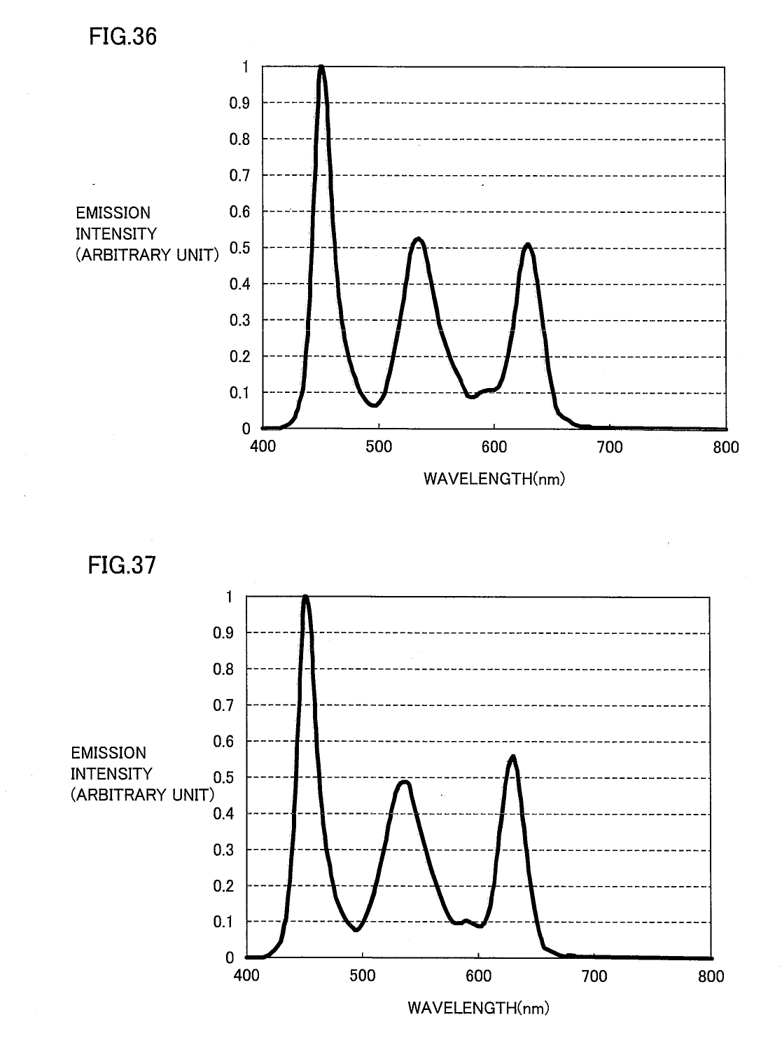

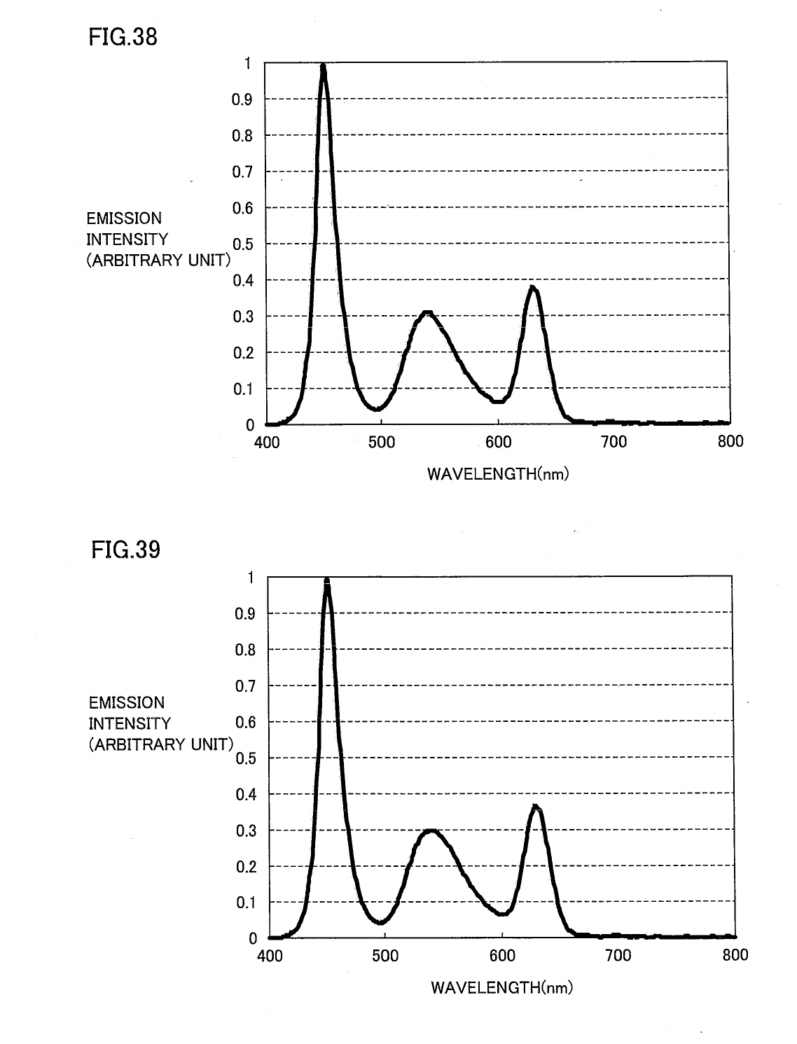

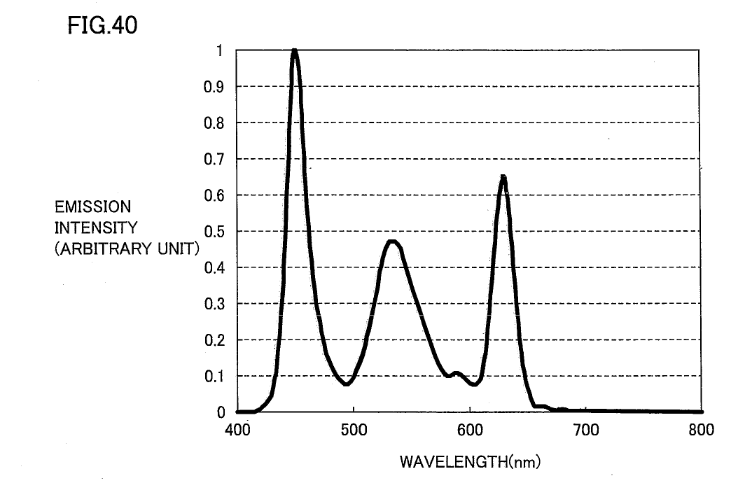

FIGS. 36 to 40 are graphs showing respective emission spectrums of the semiconductor light emitting apparatuses produced for Examples 4, 7, 10, 11, and 14. In FIGS. 36 to 40, the vertical axis represents emission intensity (in an arbitrary unit) and the horizontal axis represents wavelength (nm). The emission spectrums shown in FIGS. 36 to 40 are each adjusted such that a white point substantially represents white with a color temperature of 10000 K when an image display is structured using any of the semiconductor light emitting apparatuses for Examples 4, 7, 10, 11 and 14.

TABLE 2

| | | | | | relative | difference between local |
|---|---|---|---|---|---|---|
| | green | red | green phosphor/ | silicone resin/ | luminous | maximum and local minimum |
| | phosphor | phosphor | red phosphor (wt) | phosphor mixture (wt) | efficiency | [nm] |
| *E. 1 | ***M.E. B1 | M.E. A1 | 3.87 | 26.68 | 100.0% | 14 |
| E. 2 | M.E. B1 | M.E. A2 | 2.45 | 37.69 | 96.9% | 14 |
| E. 3 | M.E. B1 | M.E. A3 | 2.41 | 38.08 | 96.7% | 13 |
| E. 4 | M.E. B1 | M.E. A4 | 2.10 | 41.88 | 79.4% | 6 |
| E. 5 | M.E. B1 | M.E. A5 | 2.22 | 40.36 | 80.1% | 18 |
| E. 6 | M.E. B1 | M.E. A6 | 1.26 | 57.45 | 71.6% | 17 |
| E. 7 | M.E. B1 | M.E. A7 | 6.09 | 18.34 | 111.7% | 2 |
| E. 8 | M.E. B1 | M.E. A8 | 5.98 | 18.64 | 111.1% | 4 |
| E. 9 | M.E. B1 | M.E. A9 | 5.90 | 18.83 | 110.9% | 7 |
| E. 10 | M.E. B1 | M.E. A10 | 3.86 | 26.74 | 100.9% | 3 |
| E. 11 | M.E. B1 | M.E. A11 | 3.09 | 31.82 | 79.7% | 22 |
| E. 12 | M.E. B1 | M.E. A12 | 3.07 | 31.91 | 79.6% | 7 |
| E. 13 | M.E. B1 | M.E. A13 | 2.54 | 36.77 | 72.3% | 5 |
| E. 14 | M.E. B1 | M.E. A14 | 1.52 | 51.50 | 121.1% | 4 |
| E. 15 | M.E. B2 | M.E. A10 | 3.56 | 28.52 | 95.5% | 15 |
| E. 16 | M.E. B2 | M.E. A11 | 2.81 | 34.13 | 71.8% | 10 |
| E. 17 | M.E. B2 | M.E. A12 | 2.82 | 34.07 | 71.9% | 5 |
| E. 18 | M.E. B2 | M.E. A13 | 2.34 | 38.89 | 64.4% | 17 |
| E. 19 | M.E. B1 | M.E. A15 | 0.24 | 104.42 | 22.0% | 18 |
| **C.E. 1 | M.E. B1 | C.E. A1 | 3.50 | 28.87 | 98.7% | — |
| C.E. 2 | M.E. B1 | C.E. A2 | 2.01 | 43.18 | 94.1% | — |
| C.E. 3 | M.E. B1 | C.E. A3 | 1.63 | 49.47 | 79.8% | — |
| C.E. 4 | M.E. B1 | C.E. A4 | 3.06 | 31.99 | 109.3% | 30 |
| C.E. 5 | M.E. B1 | C.E. A5 | 1.90 | 44.75 | 77.1% | — |
| C.E. 6 | M.E. B1 | C.E. A6 | 1.58 | 50.34 | 72.7% | — |
| C.E. 7 | M.E. B1 | C.E. A7 | 5.33 | 20.54 | 108.7% | — |
| C.E. 8 | M.E. B1 | C.E. A8 | 4.86 | 22.18 | 109.5% | — |
| C.E. 9 | M.E. B1 | C.E. A9 | 0.20 | 108.24 | 19.7% | — |

*E. Example,
**C.E. Comparative Example,
***M.E. Manufacturing Example

In Table 2, the column of “relative luminous efficiency” indicates a relative luminous efficiency of the semiconductor light emitting apparatuses for Examples 2 to 19 with respect to the luminous efficiency of 100 of the semiconductor light emitting apparatus for Example 1. The column of “difference between local maximum and local minimum” in Table 2 refers to the minimum among respective differences between respective wavelengths at local minima of the absorption spectrum of the red phosphor and the peak wavelength of the emission spectrum of the green phosphor.

### Comparative Examples 1-9

### Semiconductor Light Emitting Apparatus

Respective semiconductor light emitting apparatuses for Comparative Examples 1 to 9 were produced similarly to Example 1. Specifically, the red phosphors prepared for Comparative Examples A1 to A9 and the green phosphor prepared for Manufacturing Example B1 were combined according to the combinations specified in Table 2. The red phosphor and the green phosphor were mixed at a weight ratio according to the column of “green phosphor/red phosphor (wt)” in Table 2. Thus, respective phosphor mixtures were obtained.

The phosphor mixtures were each mixed with a silicone resin at a weight ratio according to the column of “silicone resin/phosphor mixture (wt)” in Table 2, and the phosphor was dispersed in the silicone resin to obtain a molded resin component.

Respective molded resins obtained according to the combinations for Comparative Examples 1 to 9 were each used to seal a semiconductor light emitting device having an emission peak wavelength of 450 nm. Respective semiconductor light emitting apparatuses for Comparative Examples 1 to 9 having the structure shown in FIG. 2 were thus prepared.

### Comparison Between Examples 2 and 19 and Comparative Examples 2 and 9

Regarding the semiconductor light emitting apparatuses for Example 19 and Comparative Example 9, the semiconductor particle phosphor, namely red phosphor having a single InP core structure exhibits weak emission, and thus the semiconductor light emitting apparatuses have a low luminous efficiency. In contrast, regarding the semiconductor light emitting apparatuses for Example 2 and Comparative Example 2, it was confirmed that emission of the semiconductor particle phosphor, namely red phosphor having the core/shell structure was sufficiently strong. The factor of this difference is considered as follows. In the case where the red phosphor prepared for Comparative Example A9 is used as a semiconductor particle phosphor having a single InP core structure, the core is altered due to influences of the outside, resulting in deterioration in emission intensity.

In contrast, in the case where a semiconductor particle phosphor having the core/shell structure is used as a red phosphor, the shell serves as a protective layer for the core to reduce influences of the outside on the core. The influences of the outside may include, for example, reaction of the core with moisture and oxygen in the air in the production process of the semiconductor light emitting apparatus.

<Production of Image Display>

### Example D1

### Image Display

For Example D1, the semiconductor light emitting apparatus for Example 1 was used as a backlight light source, and a liquid crystal display device having color filters with the transmittances shown in FIG. 4 was used to produce an image display of the structure shown in FIG. 1.

### Examples D2-D19

### Image Display

For Examples D2 to D19, the semiconductor light emitting apparatuses for Examples 2 to 19 were used as respective backlight light sources, according to the relationships specified in Table 3 below. A liquid crystal display device having color filters with the transmittances shown in FIG. 4 was used to produce respective image displays for Examples D2 to D19 having the structure shown in FIG. 1.

Table 3 shows the chromaticity coordinates of a white point, a red point, a green point, and a blue point in the CIE 1976 chromaticity diagram, for the display colors of the image displays for Examples D1 to D19, as well as the NTSC ratio calculated from the chromaticity coordinates.

TABLE 3

| | semiconductor | relative | | | | | | | | | |
|---|---|---|---|---|---|---|---|---|---|---|---|
| image display | light emitting | luminous | NTSC | white point | | red point | | green point | | blue point | |
| apparatus | apparatus | efficiency | ratio | u′ | v′ | u′ | v′ | u′ | v′ | u′ | v′ |
| *E. D1 | E. 1 | 100.0% | 103.0% | 0.1904 | 0.4399 | 0.4937 | 0.5184 | 0.1016 | 0.5740 | 0.1692 | 0.1734 |
| E. D2 | E. 2 | 96.9% | 108.0% | 0.1903 | 0.4399 | 0.5081 | 0.5165 | 0.0933 | 0.5749 | 0.1682 | 0.1769 |
| E. D3 | E. 3 | 96.7% | 105.7% | 0.1902 | 0.4399 | 0.5000 | 0.5177 | 0.0953 | 0.5747 | 0.1686 | 0.1757 |
| E. D4 | E. 4 | 79.4% | 102.5% | 0.1904 | 0.4398 | 0.4880 | 0.5192 | 0.1032 | 0.5745 | 0.1715 | 0.1684 |
| E. D5 | E. 5 | 80.1% | 97.1% | 0.1902 | 0.4398 | 0.4747 | 0.5213 | 0.1075 | 0.5734 | 0.1701 | 0.1708 |
| E. D6 | E. 6 | 71.6% | 103.9% | 0.1903 | 0.4399 | 0.4946 | 0.5185 | 0.0978 | 0.5745 | 0.1689 | 0.1749 |
| E. D7 | E. 7 | 111.7% | 102.7% | 0.1902 | 0.4399 | 0.4912 | 0.5186 | 0.1050 | 0.5739 | 0.1709 | 0.1688 |
| E. D8 | E. 8 | 111.1% | 100.0% | 0.1903 | 0.4399 | 0.4826 | 0.5199 | 0.1065 | 0.5736 | 0.1710 | 0.1685 |
| E. D9 | E. 9 | 110.9% | 98.8% | 0.1902 | 0.4399 | 0.4787 | 0.5206 | 0.1074 | 0.5735 | 0.1710 | 0.1684 |
| E. D10 | E. 10 | 100.9% | 103.3% | 0.1902 | 0.4399 | 0.4942 | 0.5181 | 0.1045 | 0.5739 | 0.1705 | 0.1699 |
| E. D11 | E. 11 | 79.7% | 101.5% | 0.1903 | 0.4399 | 0.4891 | 0.5190 | 0.1051 | 0.5736 | 0.1699 | 0.1711 |
| E. D12 | E. 12 | 79.6% | 101.7% | 0.1904 | 0.4399 | 0.4892 | 0.5189 | 0.1052 | 0.5737 | 0.1703 | 0.1702 |
| E. D13 | E. 13 | 72.3% | 105.9% | 0.1903 | 0.4399 | 0.5032 | 0.5166 | 0.1042 | 0.5740 | 0.1707 | 0.1695 |
| E. D14 | E. 14 | 121.1% | 102.9% | 0.1903 | 0.4399 | 0.4935 | 0.5182 | 0.1054 | 0.5738 | 0.1706 | 0.1697 |
| E. D15 | E. 15 | 95.5% | 105.8% | 0.1902 | 0.4399 | 0.5089 | 0.5168 | 0.0879 | 0.5737 | 0.1624 | 0.1896 |
| E. D16 | E. 16 | 71.8% | 104.0% | 0.1903 | 0.4399 | 0.5037 | 0.5176 | 0.0879 | 0.5734 | 0.1615 | 0.1913 |
| E. D17 | E. 17 | 71.9% | 104.2% | 0.1903 | 0.4398 | 0.5036 | 0.5176 | 0.0883 | 0.5736 | 0.1622 | 0.1900 |
| E. D18 | E. 18 | 64.4% | 108.6% | 0.1902 | 0.4399 | 0.5194 | 0.5150 | 0.0877 | 0.5739 | 0.1626 | 0.1893 |
| E. D19 | E. 19 | 22.0% | 101.4% | 0.1904 | 0.4399 | 0.5081 | 0.5177 | 0.1001 | 0.5747 | 0.1684 | 0.1755 |
| **C.E. D1 | C.E. 1 | 98.7% | 94.8% | 0.1903 | 0.4398 | 0.4662 | 0.5225 | 0.1099 | 0.5731 | 0.1709 | 0.1685 |
| C.E. D2 | C.E. 2 | 94.1% | 96.1% | 0.1904 | 0.4399 | 0.4699 | 0.5221 | 0.1074 | 0.5735 | 0.1706 | 0.1697 |
| C.E. D3 | C.E. 3 | 79.8% | 116.1% | 0.1904 | 0.4399 | 0.5390 | 0.5114 | 0.0911 | 0.5753 | 0.1676 | 0.1788 |
| C.E. D4 | C.E. 4 | 109.3% | 93.5% | 0.1904 | 0.4398 | 0.4576 | 0.5245 | 0.1019 | 0.5738 | 0.1694 | 0.1730 |
| C.E. D5 | C.E. 5 | 77.1% | 95.3% | 0.1903 | 0.4400 | 0.4671 | 0.5223 | 0.1104 | 0.5733 | 0.1716 | 0.1669 |
| C.E. D6 | C.E. 6 | 72.7% | 89.0% | 0.1902 | 0.4399 | 0.4495 | 0.5249 | 0.1165 | 0.5724 | 0.1715 | 0.1666 |
| C.E. D7 | C.E. 7 | 108.7% | 97.1% | 0.1903 | 0.4399 | 0.4740 | 0.5212 | 0.1091 | 0.5733 | 0.1710 | 0.1682 |
| C.E. D8 | C.E. 8 | 109.5% | 91.8% | 0.1903 | 0.4399 | 0.4576 | 0.5237 | 0.1144 | 0.5726 | 0.1716 | 0.1662 |
| C.E. D9 | C.E. 9 | 19.7% | 95.6% | 0.1903 | 0.4399 | 0.4701 | 0.5217 | 0.1068 | 0.5733 | 0.1706 | 0.1688 |

*E. Example,
**C.E. Comparative Example

The chromaticity coordinates of the red point in Table 3 correspond to a chromaticity point obtained by measuring red light displayed on the image display after emitted from the semiconductor light emitting apparatus and passed through only the red color filter, with an emission measurement system (product name: MCPD-2000 (manufactured by Otsuka Electronics Co., Ltd.)).

Likewise, the chromaticity coordinates of the green point correspond to a chromaticity point obtained by measuring green light displayed on the image display after emitted from the semiconductor light emitting apparatus and passed through only the green color filter. The chromaticity coordinates of the blue point correspond to a chromaticity point obtained by measuring blue light displayed on the image display after emitted from the semiconductor light emitting apparatus and passed through only the blue color filter.

The chromaticity coordinates of the white light correspond to a chromaticity point on the image display obtained when all of the red color filter, green color filter and blue color filter are fully opened.

“NTSC ratio” in Table 3 refers to a value calculated by comparing the area of the triangle formed by connecting respective chromaticity coordinates positions of the red point, the green point and the blue point, with the chromaticity points defined by the NTSC.

### Comparative Examples D1-D9

### Image Display

For Comparative Examples D1 to D9, the semiconductor light emitting apparatuses for Comparative Examples 1 to 9 were used for respective backlight light sources, according to the relationships specified in Table 3 below, and a liquid crystal display device having color filters with the transmittances shown in FIG. 4 was used to produce respective image displays for Comparative Examples D1 to D9 with the structure shown in FIG. 1.

Table 3 shows chromaticity coordinates of a white point, a red point, a green point, and a blue point on the CIE 1976 chromaticity diagram, for the display colors of the image displays for Comparative Examples D1 to D9, as well as the NTSC ratio calculated from the chromaticity coordinates.

### Comparison Between Example 1 and Comparative Example 2

Respective red phosphors and green phosphors used for the semiconductor light emitting apparatuses for Example 1 and Comparative Example 2 are compared with each other. As shown in Table 2, the semiconductor light emitting apparatus for Example 1 uses the red phosphor for Manufacturing Example A1 and the green phosphor for Manufacturing Example B1, while the semiconductor light emitting apparatus for Comparative Example 2 uses the red phosphor for Comparative Example A2 and the green phosphor for Manufacturing Example B1.

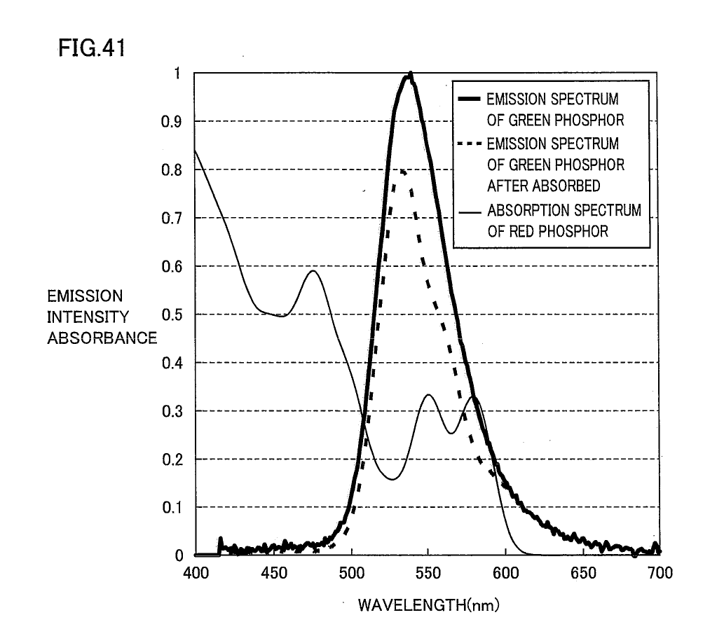

FIG. 41 is a graph illustrating a relation between the emission spectrum of the green phosphor for Manufacturing Example B1 and the absorption spectrum of the red phosphor for Manufacturing Example A1. In FIG. 41, the vertical axis represents emission intensity (in an arbitrary unit) or absorbance (in an arbitrary unit), and the horizontal axis represents wavelength (nm). FIG. 41 also shows the emission spectrum of the green phosphor after absorbed by the red phosphor.

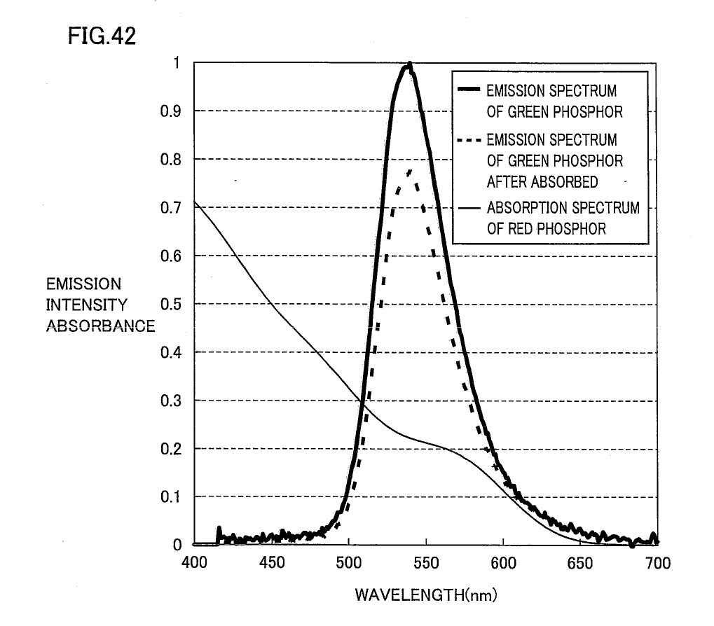

FIG. 42 is a graph illustrating a relation between the emission spectrum of the green phosphor for Manufacturing Example B1 and the absorption spectrum of the red phosphor for Comparative Example A2. In FIG. 42, the vertical axis represents emission intensity (in an arbitrary unit) or absorbance (in an arbitrary unit), and the horizontal axis represents wavelength (nm). FIG. 42 also shows the emission spectrum of the green phosphor after absorbed by the red phosphor.

Referring to FIG. 41, the absorption spectrum of the red phosphor prepared for Manufacturing Example A1 has a local minimum of absorbance at a wavelength of 528 nm, and the emission spectrum of the green phosphor prepared for Manufacturing Example B1 has a peak wavelength of 540 nm. Thus, the minimum among respective differences between respective wavelengths at local minima of absorbance of the red phosphor and the peak wavelength of the emission spectrum of the green phosphor is 12 nm. Here, the emission spectrum of the green phosphor after absorbed by the red phosphor has an emission intensity of 80% as large as that before the green phosphor is absorbed.

Referring to FIG. 42, it is seen that the absorption spectrum of the red phosphor prepared for Comparative Example A2 has no local minimum. Here, the emission intensity of the emission spectrum of the green phosphor after absorbed by the red phosphor is 78% as large as the emission intensity before the green phosphor is absorbed.

From the above-described facts, it has been found that the semiconductor light emitting apparatus produced using the red phosphor prepared for Manufacturing Example A1 has an emission intensity higher by 2% than the semiconductor light emitting apparatus using the red phosphor prepared for Comparative Example A2. It has been found accordingly that a semiconductor light emitting apparatus with a high luminous efficiency and a high color reproducibility of green light is achieved by combining a red phosphor and a green phosphor satisfying the condition that the minimum of respective differences between respective wavelengths at local minima of the absorption spectrum of the red phosphor and the peak wavelength of the emission spectrum of the green phosphor is not more than 25 nm.

Further, the absorption spectrum of the red phosphor in FIG. 41 and the absorption spectrum of the red phosphor in FIG. 42 are compared with each other. The absorption spectrum of the red phosphor in FIG. 41 has local maxima such that the red phosphor selectively absorbs light in a wavelength region at an emission intensity of not more than 30% of the maximum emission intensity of the emission spectrum of the green phosphor. When the red phosphor of the absorption spectrum as described above is used, the emission spectrum of the green phosphor after absorbed by the red phosphor is 52 nm, while the half width of the emission spectrum of the green phosphor after absorbed by the red phosphor as shown in FIG. 42 is 55 nm. Thus, the red phosphor for Manufacturing Example A1 can be used to decrease the half width of the green phosphor by 3 nm.

It is accordingly seen that a red phosphor that selectively absorbs emission of a green phosphor in a wavelength region at an emission intensity of not more than 30% relative to the maximum emission intensity can be used to reduce the half width of the emission spectrum of green phosphor 12, and enhance the color reproducibility of green.

According to “relative luminous efficiency” of Table 3, it is seen that the semiconductor light emitting apparatus for Example 1 has a luminous efficiency higher by 5.9% relative to the semiconductor light emitting apparatus for Comparative Example 2. Further, from a comparison of “NTSC ratio” between respective semiconductor light emitting apparatuses for Example 1 and Comparative Example 2 in Table 3, it is seen that the semiconductor light emitting apparatus for Example 1 has an NTSC ratio higher by 6.9% relative to the semiconductor light emitting apparatus for Comparative Example 2. Thus, it has become clear that a red phosphor selectively transmitting green light can be used to achieve an image display having its screen with a higher brightness and a higher NTSC ratio.

It has also become clear that a red phosphor having a half width of the emission spectrum of not more than 45 nm and having a standard deviation of the particle size of within 20% relative to the average particle size, like the red phosphor used for the semiconductor light emitting apparatus and the image display of the present invention, can be used to enhance the color reproducibility as well as the luminous efficiency.

### Comparison Between Example 2 and Comparative Examples 3 and 4

Respective red phosphors and respective green phosphors used for the semiconductor light emitting apparatus for Example 2 and the semiconductor light emitting apparatuses for Comparative Examples 3 and 4 are compared with each other. As shown in Table 2, the red phosphor for Manufacturing Example A2 and the green phosphor for Manufacturing Example B1 are used for the semiconductor light emitting apparatus for Example 2, the red phosphor for Comparative Example A3 and the green phosphor for Manufacturing Example B1 are used for the semiconductor light emitting apparatus for Comparative Example 3, and the red phosphor for Comparative Example A4 and the green phosphor for Manufacturing Example B1 are used for the semiconductor light emitting apparatus for Comparative Example 4.

Referring to “relative luminous efficiency” in Table 3, it is seen that the semiconductor light emitting apparatus for Example 2 has a relative luminous efficiency higher by 17.1% relative to the semiconductor light emitting apparatus for Comparative Example 3. From a comparison of “NTSC ratio” between respective semiconductor light emitting apparatuses for Example 2 and Comparative Example 3 as shown in Table 3, it is seen that the semiconductor light emitting apparatus for Example 2 has an NTSC ratio lower by 8.1% relative to the semiconductor light emitting apparatus for Comparative Example 3.

As shown in Table 1, the red phosphor for Manufacturing Example A2 has a peak wavelength of the emission spectrum of 633.9 nm, while the red phosphor for Comparative Example A3 has a peak wavelength of the emission spectrum of 647.4 nm. Thus, it has become clear that, although a red phosphor with the emission spectrum having a peak wavelength larger than 640 nm can be used to enhance the luminous efficiency of the semiconductor light emitting apparatus, the color reproducibility of the semiconductor light emitting apparatus is low.

Referring to “relative luminous efficiency” in Table 3, it is seen that the semiconductor light emitting apparatus for Example 2 has a relative luminous efficiency lower by 12.4% relative to the semiconductor light emitting apparatus for Comparative Example 4. Referring to “NTSC ratio” in Table 3, it is seen that the semiconductor light emitting apparatus for Example 2 has an NTSC ratio higher by 14.5% relative to the semiconductor light emitting apparatus for Comparative Example 4.

As shown in Table 1, the red phosphor for Manufacturing Example A2 has a peak wavelength of the emission spectrum of 633.9 nm, while the red phosphor for Comparative Example A4 has a peak wavelength of the emission spectrum of 618.3 nm. Thus, it has become clear that, although a red phosphor with the emission spectrum having a peak wavelength smaller than 620 nm can be used to enhance the color reproducibility of the semiconductor light emitting apparatus, the luminous efficiency of the semiconductor light emitting apparatus is low.

As seen from above, in order to achieve both of a high luminous efficiency and a high color reproducibility, it is preferable that the peak wavelength of the emission spectrum of the red phosphor is in a range of 620 nm to 640 nm.

<Comparison Between Binary Compound and Ternary Mixed Crystal>

Respective red phosphors used for the image displays for Examples D1, D4 and D7 are all binary compounds, while respective red phosphors used for the image displays for Examples D10 to D14 are all ternary mixed crystals. Therefore, from a comparison between the image displays for Examples D1, D4 and D7 and those for Examples D10 to D14, differences in performance between the binary compound and the ternary mixed crystal can be clarified.

Referring to “relative luminous efficiency” and “NTSC ratio” in Table 3, from a comparison between the image display for Example D1 and the image display for Example D10, it is seen that the image display for Example D10 has a relative luminous efficiency higher by 0.9% and an NTSC ratio higher by 0.3% relative to Example D1.

Likewise, referring to “luminous efficiency” in Table 3, from a comparison between the image display for Examples D4 and the image displays for Examples D11 and D12, it is seen that the image displays for Examples D11 and D12 each have a luminous efficiency higher by 0.2 to 0.3% relative to Example D4.

Referring to “NTSC ratio” in Table 3, from a comparison between respective image displays for Example D4 and Example D13, it is seen that the image display for Example D13 has an NTSC ratio higher by 3.4% relative to Example D4.

Referring to “relative luminous efficiency” and “NTSC ratio” in Table 3, from a comparison between respective image displays for Example D7 and Example D14, it is seen that the image display for Example D14 has a luminous efficiency higher by 9.4% and an NTSC ratio higher by 0.2% relative to Example D7.

As seen from the results above, a semiconductor particle phosphor of a ternary mixed crystal can be used as the red phosphor to enhance the luminous efficiency and the color reproducibility, as compared with the case where a semiconductor particle phosphor of a binary compound is used as the red phosphor.

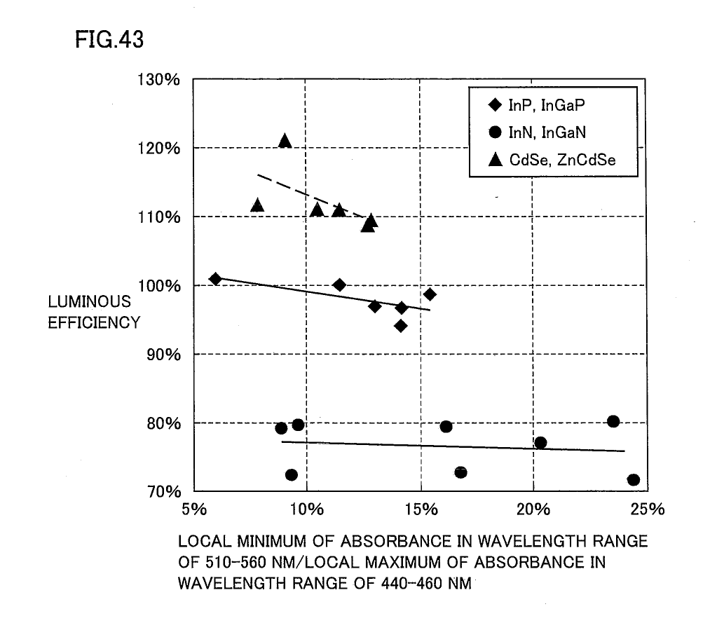

FIG. 43 is a graph illustrating a relation between an absorption spectrum of a red phosphor and a luminous efficiency of a semiconductor light emitting apparatus in which the red phosphor is used. In FIG. 43, the horizontal axis represents the value expressed in percentage as obtained by dividing the local minimum of absorbance in a green region (region where the wavelength is not less than 500 nm and not more than 570 nm) by the local maximum of absorbance in a blue region (region where the wavelength is not less than 440 nm and not more than 460 nm), and the vertical axis represents the luminous efficiency of the semiconductor light emitting apparatus in which the red phosphor is used.

Referring to FIG. 43, it is seen that a lower absorbance of the red phosphor in the green emission region tends to enhance the luminous efficiency of the semiconductor light emitting apparatus.

### Comparison Between Examples 1-3, 10 and Comparative Examples 1-2, and Between Examples 7-9, 14 and Comparative Examples 7-8

Referring to Table 2, from a comparison between respective semiconductor light emitting apparatuses for Examples 1-3 and 10 and Comparative Examples 1-2, it is seen that the semiconductor light emitting apparatuses for Examples 1-3 and 10 each have a luminous efficiency higher by 1.3 to 6.8%. From a comparison between respective semiconductor light emitting apparatuses for Examples 7-9 and 14 and those for Comparative Examples 7-8, it is seen that the semiconductor light emitting apparatuses for Examples 7-9 and 14 each have a luminous efficiency higher by 1.4 to 12.4%.

The reason is considered as follows. Regarding the absorption spectrum of the red phosphor included in the semiconductor light emitting apparatus, the absorbance in a range of 500 to 570 nm is small relative to the absorbance in a range of 440 to 460 nm, and thus emission of the green phosphor is absorbed to a relatively smaller extent by the red phosphor. It has become clear that the red phosphor with the absorption spectrum as described above can be used to enhance the luminous efficiency of the semiconductor light emitting apparatus.

### Comparison Between Examples D10-D13 and Examples D15-D18

Respective image displays for Examples D10 to D13 and respective image displays for Examples D15 to D18 are compared with each other. The image displays for Examples D15 to D18 each have an NTSC ratio higher by 2% or more. The reason is as follows. For the image displays for Examples D15 to D18 each, the green phosphor having a peak wavelength of the emission spectrum of not less than 525 nm and not more than 545 nm, and a smaller half width of the emission spectrum is used.

The green phosphor prepared for Manufacturing Example B2 has a half width of the emission spectrum of 51 nm, while the green phosphor prepared for Manufacturing Example B1 has a half width of the emission spectrum of 55 nm. Thus, the half width of the emission spectrum of the green phosphor prepared for Manufacturing Example B2 is smaller than that of the emission spectrum of the green phosphor prepared for Manufacturing Example B1. In the case where a green phosphor having a smaller half width of the emission spectrum like Manufacturing Example B2 is used, the image display has an NTSC ratio higher by approximately 2%. Thus, it has become clear that a green phosphor having a smaller half width of the emission spectrum can be used to further enhance the color reproducibility of green.

### Comparison Between Example D2 and Comparative Example D2 and Example D19 and Comparative Example D9

Respective red phosphors used for the image displays for Example D2 and Comparative Example D2 are each a semiconductor particle phosphor having the core/shell structure, while respective red phosphors used for the image displays for Example D19 and Comparative Example D9 are each a semiconductor particle phosphor having the single core structure. Respective image displays for Example D2 and Comparative Example D2 will be compared with respective image displays for Example D19 and Comparative Example D9, and the results of study on the influences of the structure of the red phosphor on the performance of the image display will be described.

Referring to “relative luminous efficiency” and “NTSC ratio” in Table 3, from a comparison between respective image displays for Example D2 and comparative Example D2, it is seen that the image display for Example D2 has a relative luminous efficiency higher by 2.8% and an NTSC ratio higher by 11.9%.

Referring to “relative luminous efficiency” in Table 3 as well, from a comparison between respective image displays for Example D19 and Comparative Example D9, it is seen that the image display for Example D19 has a relative luminous efficiency higher by 2.3% and an NTSC ratio higher by 5.8%.

It has been found from the results above that, under the condition that the minimum among respective differences between the peak wavelength of the emission spectrum of the green phosphor and respective wavelengths at local minima of the absorption spectrum of the red phosphor is not more than 25 nm, the luminous efficiency can be enhanced and the color reproducibility can also be enhanced.

Although the present invention has been described and illustrated in detail, it is clearly understood that the same is by way of illustration and example only and is not to be taken by way of limitation, the scope of the present invention being interpreted by the terms of the appended claims.

The light emitting apparatuses and the image displays according to the present invention are applicable to general illumination, decorative illumination, light emitting display apparatus, and display, for example.

What is claimed is:

1. A semiconductor light emitting apparatus comprising a semiconductor light emitting device, a green phosphor emitting green light and a red phosphor emitting red light,
said green phosphor being a rare earth activated inorganic phosphor,
said red phosphor being a semiconductor particle phosphor, and
a minimum among respective differences between respective wavelengths at local minima of an absorption spectrum of said red phosphor and a peak wavelength of an emission spectrum of said green phosphor being not more than 25 nm.

2. The semiconductor light emitting apparatus according to claim 1, wherein
one of respective wavelengths at the local minima of the absorption spectrum of said red phosphor is identical to the peak wavelength of the emission spectrum of said green phosphor.

3. The semiconductor light emitting apparatus according to claim 1, wherein
said red phosphor selectively absorbs light in a wavelength region at an emission intensity of not more than 30% of a maximum emission intensity of the emission spectrum of said green phosphor.

4. The semiconductor light emitting apparatus according to claim 1, wherein
the absorption spectrum of said red phosphor has a local minimum in a range of 500 to 570 nm.

5. The semiconductor light emitting apparatus according to claim 1, wherein
in the absorption spectrum of said red phosphor, a local minimum of absorbance in a range of 500 to 570 nm is not more than 30% of a local maximum of absorbance in a range of 440 to 460 nm.

6. The semiconductor light emitting apparatus according to claim 1, wherein
an emission spectrum of said red phosphor has a half width of not more than 45 nm.

7. The semiconductor light emitting apparatus according to claim 1, wherein
an emission spectrum of said red phosphor has a peak wavelength in a range of 620 to 640 nm.

8. The semiconductor light apparatus according to claim 1, wherein
a standard deviation of a particle size distribution of said red phosphor is within 20% of an average particle size of said red phosphor.

9. The semiconductor light emitting apparatus according to claim 1, wherein
said red phosphor is a group II-VI semiconductor particle phosphor or group III-V semiconductor particle phosphor.

10. The semiconductor light emitting apparatus according to claim 1, wherein
said red phosphor is a semiconductor particle phosphor of a mixed crystal containing at least three elements.

11. The semiconductor light emitting apparatus according to claim 10, wherein
said red phosphor is a semiconductor particle phosphor of InGaP or InGaN.

12. The semiconductor light emitting apparatus according to claim 10, wherein
said red phosphor is a semiconductor particle phosphor of ZnCdSe.

13. The semiconductor light emitting apparatus according to claim 1, wherein
said red phosphor has a core and shell structure.

14. The semiconductor light emitting apparatus according to claim 1, wherein
the emission spectrum of said green phosphor has a peak wavelength in a range of not less than 525 nm and not more than 545 nm, and
the emission spectrum of said green phosphor has a half width of not more than 55 nm.

15. The semiconductor light emitting apparatus according to claim 1, wherein
said green phosphor is an oxynitride phosphor.

16. The semiconductor light emitting apparatus according to claim 15, wherein
said green phosphor is Eu activated β-SiAlON.

17. The semiconductor light emitting apparatus according to claim 1, wherein
said semiconductor light emitting device is a GaN semiconductor light emitting device.

18. The semiconductor light emitting apparatus according to claim 1, wherein
an emission spectrum of said semiconductor light emitting device has a peak wavelength in a range of 420 to 480 nm.

19. The semiconductor light emitting apparatus according to claim 18, wherein
an emission spectrum of said semiconductor light emitting device has a peak wavelength in a range of 440 to 460 nm.

20. The semiconductor light emitting apparatus according to claim 1, wherein
an emission spectrum of said semiconductor light emitting device has a peak wavelength in a range of 390 to 420 nm.

21. An image display comprising a semiconductor light emitting apparatus as recited in claim 1 and a color filter.
